(19) United States
(12) Patent Application Publication
(10) Pub. No.: US 2024/0431147 A1
(43) Pub. Date: Dec. 26, 2024

(54) LIGHT-EMITTING DEVICE AND PRODUCTION METHOD THEREFOR

(71) Applicant: Sharp Display Technology Corporation, Kameyama City, Mie (JP)

(72) Inventor: Masayuki KANEHIRO, Kameyama City, Mie (JP)

(21) Appl. No.: 18/689,927

(22) PCT Filed: Nov. 9, 2021
(86) PCT No.: PCT/JP2021/041152

§ 371 Date: Mar. 7, 2024

(51) Int. Cl. H10K 59/122; H10K 50/115; H10K 59/131; H10K 59/35; H10K 59/80

(52) U.S. Cl. CPC H10K 59/122; H10K 50/115; H10K 59/1315; H10K 59/35; H10K 59/80518; H10K 59/879

(57) ABSTRACT

A light-emitting device includes a high-refractive-index material layer provided on a third electrode in an opening of a bank, and an auxiliary wiring line. The auxiliary wiring line is formed on the third electrode and includes an opening provided corresponding to the opening, and a peripheral edge portion thereof surrounding the opening covers a peripheral edge portion of the high-refractive-index material layer in a plan view.

### TECHNICAL FIELD

The disclosure relates to a self-luminous light-emitting device including an auxiliary wiring line, and a manufacturing method therefor.

### BACKGROUND ART

A self-luminous light-emitting device including a light-emitting element such as an organic light-emitting diode (OLED) or a quantum dot light emitting diode (QLED) has a structure in which a function layer called an electroluminescence (EL) layer including a light-emitting layer is provided between a pair of electrodes. Of the known light-emitting devices of the above-mentioned type, a light-emitting device in which an auxiliary wiring line (also referred to as an auxiliary electrode) is provided on an upper layer electrode to reduce the resistance of the upper layer electrode is known (see PTL 1, for example).

It is disclosed in PTL 1 that, as an example, an auxiliary wiring line (auxiliary electrode) is provided outside a light-emitting region (subpixel) in such a manner as to cover at least part of each of projecting structure portions provided between subpixels. It is also disclosed in PTL 1 that a non-transparent auxiliary wiring line can be used as the auxiliary wiring line in this case.

### CITATION LIST

### Patent Literature

PTL 1: JP 2019-012684 A

### SUMMARY

### Technical Problem

However, in the case where an auxiliary wiring line is formed on an upper layer electrode as in PTL 1, an EL layer such as a light-emitting layer in a lower layer is damaged by permeation of an etching solution used for patterning the auxiliary wiring line. As a result, luminous efficiency of the light-emitting device is lowered.

An aspect of the disclosure has been contrived in view of the above-described problem, and an object thereof is to provide a light-emitting device capable of suppressing the damage of an EL layer due to the permeation of the etching solution used for patterning an auxiliary wiring line and to provide a manufacturing method for the light-emitting device.

### Solution to Problem

In order to solve the above problem, a light-emitting device according to an aspect of the disclosure includes a bank provided with a first through hole; a lower layer electrode formed on the bank to close the first through hole; an upper layer electrode formed above the lower layer electrode; an EL layer including at least a light-emitting layer and formed between the lower layer electrode and the upper layer electrode to be at least partially adjacent to the lower layer electrode and the upper layer electrode; a first refractive index layer provided on the upper layer electrode in the first through hole and having a refractive index greater than 1.7; an auxiliary wiring line provided on the upper layer electrode to be adjacent to the upper layer electrode; and a second refractive index layer having a lower refractive index than the first refractive index layer and provided on the upper layer electrode to cover the first refractive index layer and the auxiliary wiring line. The auxiliary wiring line includes a second through hole that is provided corresponding to the first through hole, and a peripheral edge portion of the auxiliary wiring line surrounding the second through hole covers a peripheral edge portion of the first refractive index layer in a plan view.

In order to solve the above problem, a manufacturing method for a light-emitting device according to an aspect of the disclosure is a manufacturing method for the above-described light-emitting device according to the aspect of the disclosure, the method including: a step of forming a bank provided with the first through hole; a step of forming a lower layer electrode formed on the bank to close the first through hole; a step of forming an EL layer including at least a light-emitting layer and being at least partially adjacent to the lower layer electrode; a step of forming the upper layer electrode adjacent to the EL layer, on the EL layer; a step of forming a first refractive index layer having a refractive index greater than 1.7 on the upper layer electrode in the first through hole; a step of forming the auxiliary wiring line adjacent to the upper layer electrode, on the upper layer electrode; and a step of forming, on the upper layer electrode, the second refractive index layer having a lower refractive index than the first refractive index layer and covering the first refractive index layer and the auxiliary wiring line. In the step of forming the auxiliary wiring line, the auxiliary wiring line is formed in such a manner that the auxiliary wiring line includes the second through hole that is provided corresponding to the first through hole, and a peripheral edge portion of the auxiliary wiring line surrounding the second through hole covers a peripheral edge portion of the first refractive index layer in a plan view.

### Advantageous Effects of Disclosure

According to the aspect of the disclosure, it is possible to provide a light-emitting device capable of suppressing the damage of the EL layer due to the permeation of an etching solution used for patterning the auxiliary wiring line and to provide a manufacturing method for the light-emitting device.

### BRIEF DESCRIPTION OF DRAWINGS

FIG. 1 is a plan view illustrating an example of a schematic configuration of main portions of a display device according to a first embodiment.

FIG. 2 is a plan view illustrating an example of a schematic configuration of main portions of the display device according to the first embodiment, as viewed from above an auxiliary wiring line of each of subpixels of the display device.

FIG. 3 is a cross-sectional view illustrating a schematic configuration of the main portions of the display device according to the first embodiment.

FIG. 4 is a plan view in which a second electrode and an auxiliary wiring line of each subpixel in the display device according to the first embodiment are illustrated side by side.

FIG. 5 is a diagram schematically illustrating an example of a layered structure in each light-emitting region of a light-emitting element of the display device according to the first embodiment.

FIG. 6 is a flowchart illustrating an example of a manufacturing process of the display device according to the first embodiment.

FIG. 7 is a flowchart illustrating an example of a formation process of a light-emitting element layer indicated in step S4 in FIG. 6.

FIG. 8 is a cross-sectional view illustrating an example of a formation process of main portions of the light-emitting element layer illustrated in FIG. 7.

FIG. 9 is a cross-sectional view illustrating an example of a formation process of main portions of a light-emitting element layer when a known method for forming an auxiliary wiring line on an upper layer electrode is applied to the manufacturing method for the display device according to the first embodiment.

FIG. 10 is a cross-sectional view illustrating an optical path of light in a light-emitting region of a light-emitting element layer of the display device according to the first embodiment.

FIG. 11 is a cross-sectional view illustrating an optical path of light in a light-emitting region of a known light-emitting element.

FIG. 12 is a cross-sectional view illustrating a schematic configuration of main portions of a light-emitting element layer of a display device according to a second embodiment, together with an optical path of light in a light-emitting region.

FIG. 13 is a plan view illustrating an example of a schematic configuration of main portions of a display device according to a third embodiment, as viewed from above an auxiliary wiring line of a subpixel of the display device.

FIG. 14 is a plan view in which a second electrode and an auxiliary wiring line of a subpixel in the display device according to the third embodiment are illustrated side by side.

FIG. 15 is a diagram schematically illustrating an example of a layered structure in each light-emitting region of a light-emitting element of each color in a display device according to a fourth embodiment.

FIG. 16 is a graph showing a relationship between a layer thickness of ITO on a reflective electrode and light extraction efficiency at a second electrode in each light-emitting region of light-emitting elements of respective colors in the display device according to the fourth embodiment.

FIG. 17 is a cross-sectional view illustrating a schematic configuration of main portions of a light-emitting element layer of a display device according to a fifth embodiment, together with an optical path of light in a light-emitting region in the light-emitting element layer.

FIG. 18 is a cross-sectional view illustrating a schematic configuration of main portions of a light-emitting element layer of a display device according to a sixth embodiment, together with an optical path of light in a light-emitting region in the light-emitting element layer.

### DESCRIPTION OF EMBODIMENTS

### First Embodiment

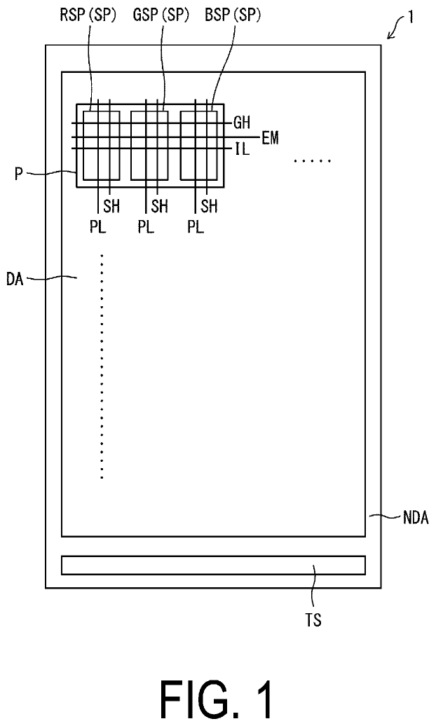

An embodiment of the disclosure will be described below with reference to FIG. 1 to FIG. 11. Note that, in the following, description is made using, as an example, a case in which a light-emitting device according to the present embodiment is a display device.

### Schematic Configuration of Display Device

FIG. 1 is a plan view illustrating an example of a schematic configuration of main portions of a display device 1 (light-emitting device) according to the present embodiment.

As illustrated in FIG. 1, the display device 1 includes a display region DA (pixel region) including a plurality of subpixels SP and a frame region NDA provided around the display region DA, surrounding the display region DA.

The frame region NDA is a non-display region. In the frame region NDA, a terminal portion TS into which is input a signal for driving each subpixel SP is provided. Note that the terminal portion TS may be provided with an electronic circuit board (not illustrated) such as an integrated circuit (IC) chip and a flexible printed circuit (FPC) board, for example.

In the display region DA, for example, a plurality of wiring lines including a plurality of gate wiring lines GH, a plurality of light emission control lines EM, and a plurality of initialization potential lines IL are provided to extend in a row direction. Further, in the display region DA, for example, a plurality of wiring lines including a plurality of power source lines PL and a plurality of source wiring lines SH are provided to extend in a column direction. The plurality of subpixels SP are provided in a matrix shape, for example, respectively corresponding to intersecting portions of the gate wiring lines GH and the source wiring lines SH.

The display device 1 includes, as the subpixels SP, a subpixel RSP of a red color (R) that emits red light, a subpixel GSP of a green color (G) that emits green light, and a subpixel BSP of a blue color (B) that emits blue light, for example. Note that, in the present embodiment, when there is no particular need to distinguish between the subpixel RSP, the subpixel GSP, and the subpixel BSP, these are collectively referred to simply as “subpixel SP”.

FIG. 1 illustrates an example in which the display device 1 includes a plurality of pixels P each including the subpixels SP of three colors, exhibiting the three different colors RGB, and the plurality of pixels P are provided in a matrix shape in the display region DA. Further, FIG. 1 illustrates an example in which the subpixels SP of the colors RGB are repeatedly arrayed side-by-side in this order in an extending direction of the gate wiring line GH, and a plurality of the subpixels SP are arrayed side-by-side for each color along an extending direction of the source wiring line SH. However, the above is merely an example, and the display device 1 may include subpixels SP other than the subpixels of RGB. Further, the arrays of the subpixels SP are also not limited to the above arrays.

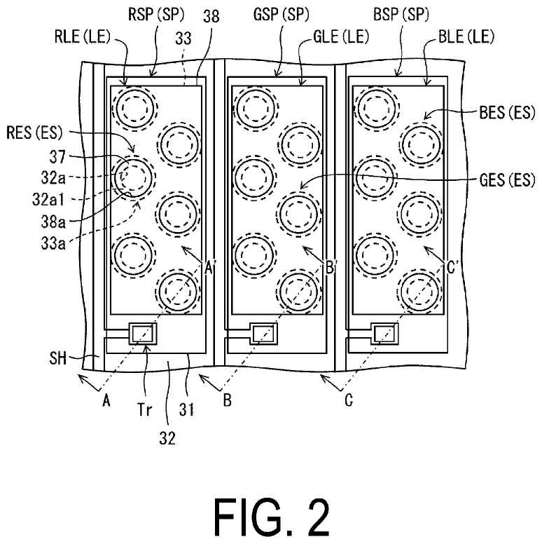

FIG. 2 is a plan view illustrating an example of a schematic configuration of the main portions of the display device 1 according to the present embodiment, as viewed from above an auxiliary wiring line 38 of each subpixel SP.

The display device 1 is a self-luminous display device. As illustrated in FIG. 2, in each subpixel SP, a self-luminous light-emitting element LE is formed. In each light-emitting element LE, a plurality of light-emitting regions (small hole light-emitting regions) ES partitioned into small hole shapes by a bank 32 and the auxiliary wiring line 38 are formed. The light-emitting regions ES are separated from each other in a plan view by the bank 32 and the auxiliary wiring line 38 serving as a non-light-emitting region. Accordingly, the display device 1 has a configuration in which the light-emitting element LE including the plurality of light-emitting regions ES each surrounded by the bank 32 and the auxiliary wiring line 38 is provided in each subpixel SP.

According to the present embodiment, since a plurality of small hole-shaped light-emitting regions are provided in one subpixel SP (in other words, one light-emitting element LE) as described above, it is possible to improve the luminance of the display device 1 compared to the related art.

In the subpixel RSP, a light-emitting element RLE of a red color that emits red light (red light-emitting element) is provided. In the subpixel GSP, a light-emitting element GLE of a green color that emits green light (green light-emitting element) is provided. In the subpixel BSP, a light-emitting element BLE of a blue color that emits blue light (blue light-emitting element) is provided. Note that the luminescent colors of the light-emitting regions ES of the light-emitting elements LE provided in the same subpixel SP are all the same. Accordingly, in the subpixel RSP of a red color, a plurality of light-emitting regions RES of a red luminescent color (red light-emitting regions) are provided as the light-emitting regions ES. In the subpixel GSP of a green color, a plurality of light-emitting regions GES of a green luminescent color (green light-emitting regions) are provided as the light-emitting regions ES. In the subpixel BSP of a blue color, a plurality of light-emitting regions BES of a blue luminescent color (blue light-emitting regions) are provided as the light-emitting regions ES. Thus, the display region DA is provided with a plurality of the light-emitting regions ES in the plurality of light-emitting elements LE having luminescent colors different from one another.

Note that, in the present embodiment, when there is no particular need to distinguish between the light-emitting element RLE, the light-emitting element GLE, and the light-emitting element BLE, the light-emitting element RLE, the light-emitting element GLE, and the light-emitting element BLE are collectively simply referred to as “light-emitting element LE”. Further, note that, in the present embodiment, when there is no particular need to distinguish between the light-emitting region RES, the light-emitting region GES, and the light-emitting region BES, the light-emitting region RES, the light-emitting region GES, and the light-emitting region BES are collectively simply referred to as “light-emitting region ES”. Further, the individual layers in the light-emitting regions ES of the light-emitting elements LE are also similarly collectively named when there is no particular need to distinguish between the light-emitting region RES, the light-emitting region GES, and the light-emitting region BES.

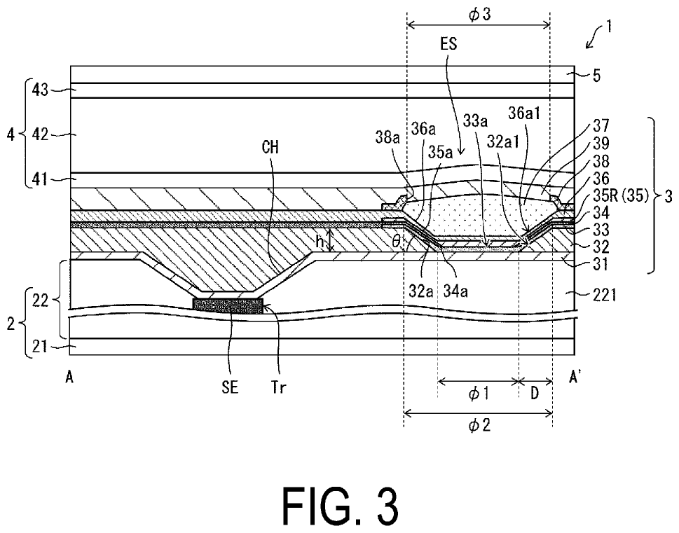

FIG. 3 is a cross-sectional view illustrating a schematic configuration of main portions of the display device 1 according to the present embodiment. Note that FIG. 3 illustrates, as an example, a cross section corresponding to the cross section taken along line A-A′ illustrated in FIG. 2 in the display device 1 provided with an EL layer 35R including the light-emitting layer that emits red light. However, the cross section taken along the line A-A′, the cross section taken along line B-B′, and the cross section taken along line C-C′ illustrated in FIG. 2 have the same cross-sectional configuration except that the light-emitting elements LE in each cross section include light-emitting layers that emit light of colors different from one another. Therefore, in the following description, the schematic configuration of the cross section taken along the line A-A′ will be described as a configuration common to the cross section taken along the line A-A′, the cross section taken along the line B-B′, and the cross section taken along the line C-C′ without distinguishing the configuration for each subpixel SP (light-emitting element LE).

As illustrated in FIG. 3, the display device 1 includes an array substrate 2, a light-emitting element layer 3, and a sealing layer 4 in this order. In the following, a direction from the array substrate 2 toward the sealing layer 4 is referred to as an upward direction, and a direction opposite thereof is referred to as a downward direction. Further, in the following, a layer formed in a process prior to that of a layer being compared is referred to as a “lower layer,” and a layer formed in a process after that of a layer being compared is referred to as an “upper layer”. Note that, as illustrated in FIG. 3, a function layer 5 selected as appropriate according to application may be provided on the sealing layer 4 in the display device 1.

The array substrate 2 has a configuration in which a thin film transistor layer 22 is provided on an insulating substrate 21.

The insulating substrate 21 is a support body that supports the individual layers from the thin film transistor layer 22 to the function layer 5. The insulating substrate 21 may be, for example, an inorganic substrate made of an inorganic material such as glass, quartz, or ceramics, or a flexible substrate made primarily of resin such as polyethylene terephthalate or polyimide. When the insulating substrate 21 is a flexible substrate, the insulating substrate 21 may be formed of a resin film (resin layer) such as a polyimide film, or may be formed of two resin films and an inorganic insulating film interposed between these resin films.

Further, on a surface of the insulating substrate 21, a barrier layer may be provided to prevent foreign matters such as water and oxygen from entering the thin film transistor layer 22 and the light-emitting element layer 3. Such a barrier layer can be constituted by a silicon oxide film, a silicon nitride film, a silicon oxynitride film, or a layered film of these, formed by chemical vapor deposition (CVD), for example.

When the display device 1 is a top-emitting type display device configured to emit light from a side opposite to the insulating substrate 21 (in other words, from the side of a third electrode 36 to be described below in the light-emitting element layer 3). Therefore, the insulating substrate 21 to be used is not particularly limited.

A subpixel circuit that controls the light-emitting element layer 3 and a plurality of wiring lines including the gate wiring line GH and the source wiring line SH that are connected to the subpixel circuit are formed in the thin film transistor layer 22. The subpixel circuit is provided for each subpixel SP in correspondence with each subpixel SP in the display region DA. The subpixel circuit includes a plurality of thin film transistors including a thin film transistor Tr illustrated in FIG. 2 and FIG. 3. The plurality of thin film transistors are electrically connected to a plurality of wiring lines including wiring lines such as the gate wiring line GH and the source wiring line SH described above. Note that, as these thin film transistors, a known structure can be employed, and the structure is not particularly limited.

On a surface of the thin film transistor layer 22, provided is a flattening film 221 covering the plurality of thin film transistors, flattening surfaces of the plurality of thin film transistors provided in the thin film transistor layer 22 and including the thin film transistor Tr. The flattening film 221 can be formed of, for example, a coatable organic insulating material such as a polyimide or acrylic resin.

The light-emitting element layer 3 includes the plurality of light-emitting elements LE described above. Further, the light-emitting element layer 3 is provided with the plurality of light-emitting regions ES described above in each light-emitting element LE. As described above, these light-emitting regions ES include the light-emitting region RES, the light-emitting region GES, and the light-emitting region BES in terms of pixel units. Note that, in the present embodiment, as described above, a plurality of light-emitting regions ES having the same luminescent color are provided in the same subpixel SP.

The light-emitting element layer 3 includes a first electrode 31, the bank 32 (wall body), a second electrode 33, an edge cover 34, an EL layer 35, the third electrode 36, a high-refractive-index material layer 37, the auxiliary wiring line 38 (auxiliary electrode), and a low-refractive-index material layer 39 in this order from the thin film transistor layer 22 side.

The light-emitting element LE includes, in each light-emitting region ES, the second electrode 33, the EL layer 35 including at least a light-emitting layer, the third electrode 36, the high-refractive-index material layer 37 (first refractive index layer), and the low-refractive-index material layer 39 (second refractive index layer). Note that layers between the second electrode 33 and the third electrode 36 are collectively referred to as the EL layer 35 in the present embodiment.

The first electrode 31 is a connection electrode of the thin film transistor Tr in each subpixel circuit. As illustrated in FIG. 2 and FIG. 3, the first electrode 31 is formed on the flattening film 221 in an island shape for each subpixel SP, covering the entire corresponding subpixel SP (in other words, the entire subpixel region) in a plan view, for example. The first electrode 31 in each subpixel SP is connected (electrically connected), via a contact hole CH provided in the flattening film 221 for each subpixel SP, to a source electrode SE of the thin film transistor Tr of the subpixel SP connected to the source wiring line SH.

Further, on the flattening film 221, the bank 32 including an opening 32a (first through hole) for exposing part of the first electrode 31 is formed covering the first electrode 31 as a film for forming the light-emitting region ES.

The bank 32 is an organic insulating film formed of a photosensitive resin such as a polyimide or acrylic resin, for example.

As illustrated in FIG. 2 and FIG. 3, the bank 32 according to the present embodiment is provided with a plurality of the openings 32a (through holes, craters) as the through holes (first through holes) each formed in a small hole shape, for example, and including an opening sidewall 32a1 being inclined. In the present embodiment, as illustrated in FIG. 2, the plurality of openings 32a having the small hole shape described above are provided in one subpixel SP.

Desirably, the openings 32a are formed with opening sizes (diameters) thereof decreasing as heading toward a lower side. Accordingly, desirably, the opening sidewall 32a1, which is an internal wall of the opening 32a and surrounds the opening 32a, is inclined with the opening size of the opening 32a decreasing as heading toward the lower side, forming the opening 32a having a reverse tapered shape in a cross-sectional view. In other words, preferably, the opening sidewall 32a1 of the opening 32a is provided with an inclined face having a tapered shape in which the opening size of the opening 32a decreases as heading toward the lower side (that is, an inclined face having a reverse tapered shape).

As illustrated in FIG. 3, in the bank 32, when θ (°) is defined as an angle (inclination angle) formed by the inclined face (in other words, the inclined opening sidewall 32a1) and the lower face (bottom face) of the bank 32, θ is preferably 15°≤θ≤40°, and more preferably 20°≤θ≤30°.

Further, as illustrated in FIG. 3, when φ1 (μm) is defined as the opening size (diameter) at a lower side (lower end side) of the bank 32, it is preferable for φ1 to satisfy a relation of 10 μm≤φ1≤20 μm, and more preferable to satisfy a relation of 12 μm≤φ1≤15 μm. When φ2 (μm) is defined as the opening size (diameter) at an upper side (upper end side) of the bank 32, it is preferable for φ2 to satisfy a relation of 12 μm≤φ2≤65 μm (where φ2>φ1), and more preferable to satisfy a relation of 18 μm≤φ2≤32 μm (where φ2>φ1).

In the present embodiment, the upper side (upper end side) of the bank 32 refers to the second electrode 33 side of the bank 32 (that is, a formation face side of the second electrode 33). In the present embodiment, the lower side (lower end side) of the bank 32 refers to the opposite side to the upper side (the opposite side to the second electrode 33 side), that is, the insulating substrate 21 side of the bank 32. The opening size at the lower side (lower end side) of the bank 32 refers to an opening diameter on the lower end side of the opening 32a of the bank 32. The opening size on the upper side (upper end side) of the bank 32 refers to an opening diameter on the upper end side of the opening 32a of the bank 32.

As illustrated in FIG. 3, when h (μm) is defined as a height of the bank 32 at a portion other than the contact hole CH and the opening 32a, it is preferable for h to satisfy a relation of 1 μm≤h≤4 μm, and more preferable to satisfy a relation of 2 μm≤h≤3 μm. The height of the bank 32 at a portion other than the contact hole CH and the opening 32a is equal to the height (thickness) between the upper end and the lower end of the opening 32a of the bank 32.

The second electrode 33 is a lower layer electrode of a pair of electrodes interposing the EL layer 35 therebetween in the light-emitting element LE. The second electrode 33 is formed on the bank 32 along a surface of the bank 32, covering the openings 32a, including the inclined faces of the opening sidewalls 32a1, of the bank 32 positioned in each subpixel SP.

Thus, the second electrode 33 is provided with an inclined face having a tapered shape and formed on the opening sidewall 32a1 along the opening sidewall 32a1.

Further, at each opening 32a of the bank 32, the second electrode 33 is connected (electrically connected) to the first electrode 31 by being in contact with part of the first electrode 31 exposed from these openings 32a. Therefore, the second electrode 33 is electrically connected, via the first electrode 31, to the source electrode SE of the thin film transistor Tr connected to the source wiring line SH.

As illustrated in FIG. 2, the second electrode 33 is formed as an island electrode (subpixel electrode) in an island shape for each subpixel SP, for example, overlapping a portion of the first electrode 31 in each subpixel SP. Therefore, the first electrode 31 and the second electrode 33 are provided in common to each light-emitting region ES in each subpixel SP, and one first electrode 31 and one second electrode 33 are provided in each subpixel SP (in other words, each light-emitting element LE).

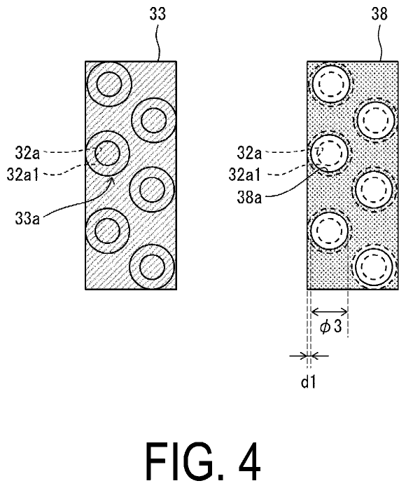

FIG. 4 is a plan view in which the second electrode 33 and the auxiliary wiring line 38 of each subpixel SP in the display device 1 according to the present embodiment are illustrated side by side. In FIG. 4, the opening 32a of the bank 32 is indicated by a dotted line in order to indicate a relationship between the opening 32a, and a recessed portion 33a (trench portion) of the second electrode 33 and an opening 38a of the auxiliary wiring line 38.

In the present embodiment, as illustrated in FIG. 2 and FIG. 4, the second electrode 33 includes the plurality of recessed portions 33a along the opening shape of the bank 32, and is formed in, for example, a rectangular shape in a plan view. The second electrode 33 is in contact with the first electrode 31 exposed from the opening 32a of the bank 32 at the bottom face of the recessed portion 33a.

The second electrode 33 is covered with the edge cover 34 including a plurality of openings 34a (third through holes), where the opening 34a (third through hole) is provided corresponding to each opening 32a of the bank 32. The edge cover 34 is formed on the bank 32 provided with the second electrode 33 in such a manner as to cover the upper face of the bank 32 and a portion of the second electrode 33 located on the upper face and the opening sidewall 32a1 of the bank 32. The bottom face of the recessed portion 33a of the second electrode 33 is not covered with the edge cover 34 and is exposed from the openings 34a of the edge cover 34.

The edge cover 34 is an insulating layer for preventing a short circuit between the second electrode 33 and the third electrode 36 in each light-emitting region ES resulting from the thinning of the EL layer 35, an electric field concentration, or the like at the upper end of the opening 32a of the bank 32.

As a material of the edge cover 34, an inorganic insulating film such as a silicon nitride film or a silicon oxide film, or an organic insulating film made of a photosensitive resin such as a polyimide or acrylic resin is used, for example.

In the present embodiment, as illustrated in FIG. 3, in the edge cover 34, there is formed the opening 34a configured to cover a portion of the second electrode 33 located on the upper face and the opening sidewall 32a1 of the bank 32 and expose the bottom face of the recessed portion 33a. Because of this, the opening size (diameter) of each opening 34a of the edge cover 34 is approximately equal to the opening diameter on the lower end side of the opening 32a of the bank 32.

Accordingly, the opening size (diameter) of the edge cover 34 according to the present embodiment is preferably in a range from 10 μm to 20 μm, and more preferably in a range from 12 μm to 15 μm.

The display device 1 according to the present embodiment is a top-emitting type display device, and the third electrode 36, which is an electrode on the light extraction face side, is transparent. The auxiliary wiring line 38 provided on the third electrodes 36 as shown in FIG. 3 has the same outer shape as the second electrode 33 as shown in FIG. 4, and the opening 38a (second through hole) is provided corresponding to each opening 32a.

In the present embodiment, as illustrated in FIG. 3, the edge cover 34 covers a portion of the second electrode 33 located on the opening sidewall 32a1. Because of this, in the present embodiment, it is desirable to use an insulating edge cover having transparency for the edge cover 34. With this, light reflected at the inclined face of the second electrode 33 can be extracted to the outside via the edge cover 34 provided on the opening sidewall 32a1 and covering the inclined face of the second electrode 33.

Accordingly, in the present embodiment, a portion of the EL layer 35 not covered with the auxiliary wiring line 38 in a plan view (in other words, a region in the opening 32a of the auxiliary wiring line 38) becomes the light-emitting region ES of each subpixel SP (in other words, each light-emitting element LE).

In the present embodiment, as described above, the portion of the second electrode 33 located on the upper face and the opening sidewall 32a1 of the bank 32 is covered with the edge covers 34. Due to this, in the EL layer 35, a portion on the bottom face of the recessed portion 33a of the second electrodes 33 is in contact with each of the second electrode 33 and the third electrode 36, but a portion on the opening sidewall 32a1 is not in contact with the second electrode 33. Accordingly, part of the EL layer 35 is provided adjacent to the second electrode 33 and the third electrode 36, and a portion of the second electrode 33 on the opening sidewall 32a1 functions not as an electrode but as a reflective layer. Therefore, a portion of the EL layer 35 on the opening sidewall 32a1 does not emit light, and a portion of the EL layer 35 provided adjacent to the second electrode 33 and the third electrode 36 (in the present embodiment, a portion of the second electrode 33 on the bottom face of the recessed portion 33a) serves as a light-emitting region of the light-emitting layer in the EL layer 35. However, as described above, since the portion of the second electrode 33 on the opening sidewall 32a1 functions as a reflective layer, light emitted from the light-emitting layer and reflected can also be extracted from a portion on the opening sidewall 32a1 in a plan view. Accordingly, in the disclosure, a region in which the light-emitting element LE emits light to the outside is referred to as a light-emitting region ES of each subpixel SP (in other words, each light-emitting element LE) regardless of whether the region is a light-emitting region of the light-emitting layer.

Note that a thickness of the edge cover 34 is not particularly limited as long as the edge cover 34 is formed to a thickness capable of insulating the second electrode 33 from the third electrode 36. The edge cover 34 can be set to a thickness similar to that of a known insulating layer or edge cover, for example. However, to suppress step disconnection of the third electrode 36, the edge cover 34 is preferably thinly formed within a range in which insulation is possible.

The third electrode 36 is an upper layer electrode of the light-emitting element LE. The third electrode 36 is formed in a solid shape in the subpixel region where the plurality of subpixels SP are formed, as a common electrode common to all the subpixels SP.

One of the second electrode 33 and the third electrode 36 is an anode (anode electrode) and the other is a cathode (cathode electrode). The anode is an electrode that supplies positive holes (holes) to the EL layer 35 when a voltage is applied. The cathode is an electrode that supplies electrons to the EL layer 35 when a voltage is applied.

In the present embodiment, a light-transmissive electrode having transparency is used for the third electrode 36, and a so-called reflective electrode having light reflectivity is used for the second electrode 33.

As the third electrode 36, for example, a light-transmissive electrode made of indium tin oxide (ITO) is suitably used to support the high-refractive-index material layer 37.

The auxiliary wiring line 38 is formed in an island shape on the third electrode 36 while being in contact with part of the third electrode 36 in order to lower the resistance of the third electrode 36 formed of the transparent conductive film as described above and suppress an IR (current-wiring line resistance) drop. Thus, the auxiliary wiring line 38 has the same potential as that of the third electrode 36.

The auxiliary wiring line 38 is a metal wiring line. A metal material having higher electrical conductivity than the third electrode 36, such as silver (Ag) or an Ag alloy, is used for the auxiliary wiring line 38.

As the second electrode 33, used is a reflective electrode made of a light-reflective material, such as a metal of Ag or aluminum (Al), or an alloy containing these metals. The second electrode 33 may be achieved as a reflective electrode by layering a light-transmissive material and a light-reflective material. As an example, in the present embodiment, for the second electrode 33, a reflective electrode formed of a layered body obtained by layering an Ag alloy containing Ag and ITO in the order of ITO/Ag alloy/ITO from the lower layer side, a layered body obtained by layering Ag and ITO in the order of ITO/Ag/ITO from the lower layer side, a layered body obtained by layering Al and indium zinc oxide (IZO) in the order of Al/IZO from the lower layer side, or the like is used.

The first electrode 31 may be a light-transmissive electrode or may be a reflective electrode. Examples of the light-transmissive electrode used for the first electrode 31 include a light-transmissive electrode made of a thin film of ITO, IZO, silver nanowire (AgNW) or a magnesium-silver (MgAg) alloy, a thin film of Ag, or the like. Examples of the reflective electrode used for the first electrode 31 include a reflective electrode made of the light-reflective material exemplified above. Similar to the second electrode 33, the first electrode 31 may also be achieved as a reflective electrode by layering a light-transmissive material and a light-reflective material.

The EL layer 35 is formed in an island shape along the surface of the second electrode 33 and part of the surface of the edge covers 34 in such a manner as to cover the bottom face of the recessed portion 33a and the inclined face of the recessed portion 33a covered with the edge cover 34 in the second electrode 33.

Thus, the EL layer 35 is provided with a taper-shaped inclined face formed on the inclined face of the edge cover 34 covering the inclined face of the second electrode 33 along the inclined face of the edge cover 34.

The third electrode 36 is formed on the EL layer 35 and the edge cover 34 along the surfaces of the EL layer 35 and the edge cover 34 in such a manner as to cover the surface of the EL layer 35 including the inclined face of the EL layer 35.

Thus, the third electrode 36 is provided with an inclined face having a tapered shape and formed on the inclined face of the EL layer 35, along that inclined face.

For this reason, each of the second electrode 33, the EL layer 35, and the third electrode 36 includes, in the opening 32a of the bank 32, a recessed portion (trench portion) including a taper-shaped sidewall (internal wall, inclined face) following the shape of the opening sidewall 32a1 of the opening 32a. The EL layer 35 is provided with a recessed portion 35a as the recessed portion discussed above. The third electrode 36 is provided with a recessed portion 36a as the recessed portion discussed above.

The light-emitting element LE may be, for example, a quantum dot light-emitting diode (QLED) or may be an organic light-emitting diode (OLED). When the light-emitting element LE is a QLED, a quantum dot (QD) light-emitting layer including quantum dots (QDs) as a light-emitting material is used as the light-emitting layer. When the light-emitting element LE is an OLED, an organic light-emitting layer that uses an organic light-emitting material as the light-emitting material is used for the light-emitting layer.

When the light-emitting element LE is a QLED, positive holes and electrons recombine inside the light-emitting layer in response to a drive current between the anode and the cathode, and light is emitted when excitons generated in this manner transition from a conduction band level to a valence band level of the QDs. When the light-emitting element LE is an OLED, positive holes and electrons recombine inside the light-emitting layer in response to a drive current between the anode and the cathode, and light is emitted as a result of excitons, which are generated by the recombination, falling into a ground state. However, the light-emitting element LE may be a light-emitting element other than the OLED or the QLED (for example, an inorganic light-emitting diode).

Note that the EL layer 35 may be a single layer type formed only of a light-emitting layer, or may be a multi-layer type including a function layer other than the light-emitting layer. The EL layer 35 may include, for example, at least one layer of a hole injection layer (HIL), a hole transport layer (HTL), an electron transport layer (ETL), and an electron injection layer (EIL) in addition to the light-emitting layer.

When the light-emitting element LE is a QLED, each of the HIL, the HTL, the ETL, and the EIL may be formed of an organic material or may be formed of an inorganic material. When the light-emitting element LE is an OLED, an organic material is used for each of the HIL, the HTL, the ETL, and the EIL, for example.

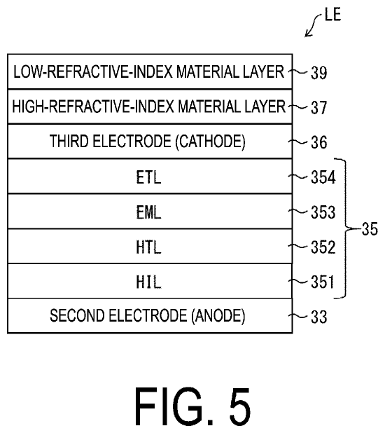

FIG. 5 is a diagram schematically illustrating an example of a layered structure of each light-emitting region ES of the light-emitting element LE of the display device 1 according to the present embodiment. FIG. 5 illustrates, as an example, a case in which the display device 1 has a known structure. In this case, the second electrode 33 is an anode (pattern anode) patterned in an island shape, and the third electrode 36 is a cathode (common cathode) provided in common to all the subpixels SP.

In the example illustrated in FIG. 5, an HIL 351, an HTL 352, an EML 353, and an ETL 354 are formed as the EL layer 35 in that order from the second electrode 33 side, between the second electrode 33 and the third electrode 36. Note that, in the layering order described above, the second electrode 33 serves as an anode and the third electrode 36 serves as a cathode as described above. The display device 1 may have an inverted structure, and thus the second electrode 33 may be a cathode and the third electrode 36 may be an anode. In this case, the layering order of the EL layer 35 is reversed from that in FIG. 5.

Hereinafter, a case in which the light-emitting element LE is a QLED and the EL layer 35 is a nano LED (light emitting diode) layer including a QD light-emitting layer containing nano-sized QDs as a light-emitting material will be described as an example.

Since the QLED utilizes narrowed light-emission characteristics of the QD as a light-emitting material, it is unnecessary to narrow the light emission spectrum by the microcavity effect with a reflective electrode and a translucent electrode, which is applied to the known OLED. Thus, a transparent electrode can be used for the second electrode 33, which is an upper layer electrode. Since the QD as a light-emitting material is an inorganic material, process tolerability is high, and the patterning process of the auxiliary wiring line 38 can be carried out after the light-emitting layer formation process.

However, the present embodiment is not limited thereto, and the light-emitting element LE may be an OLED or may be an inorganic light-emitting diode as described above.

The HIL 351 has hole transport properties and promotes the injection of positive holes from the second electrodes 33 into the EML 353. A known hole transport material can be used for the HIL 351. Examples of the hole transport material used for the HIL 351 include a composite (abbreviated “PEDOT:PSS”) of poly(3,4-ethylenedioxythiophene) (PEDOT) and polystyrene sulfonic acid (PSS), nickel oxide (NiO), and copper thiocyanate (CuSCN). Only one type of these hole transport materials may be used, or two or more types thereof may be mixed and used as appropriate. Among these hole transport materials, the hole transport material used for the HIL 351 more desirably contains NiO nanoparticles due to high tolerability against a patterning process of the EML 353 described below.

The HTL 352 has hole transport properties and transports the positive holes injected from the HIL 351 to the EML 353. A known hole transport material can be used for the HTL 352. Examples of the hole transport material used for the HTL 352 include poly[(9,9-dioctylfluorenyl-2,7-diyl)-co-(4,4′-(N-4-sec-butylphenyl)) diphenylamine)] (abbreviated “TFB”), poly[N,N′-bis(4-butylphenyl)-N,N′-bis(phenyl)-benzidine] (abbreviated “p-TPD”), and polyvinyl carbazole (abbreviated “PVK”). Only one type of these hole transport materials may be used, or two or more types thereof may be mixed and used as appropriate.

The ETL 354 has electron transport properties and transports electrons from the third electrode 36 to the EML 353. A known electron transport material can be used for the ETL 354. Examples of the electron transport material used for the ETL 354 include zinc oxide (ZnO) and magnesium zinc oxide (MgZnO). Only one type of these electron transport materials may be used, or two or more types thereof may be mixed and used as appropriate.

The EML 353 is a light-emitting layer that emits light due to the occurrence of recombination of positive holes transported from the second electrode 33 (anode) and electrons transported from the third electrode 36 (cathode).

When the light-emitting element LE is a QLED, a QD light-emitting layer including a QD as a light-emitting material is used for the EML 353 as discussed above.

The QD is not particularly limited, and various known QDs can be employed. The QD may include, for example, a semiconductor material formed of an element of at least one type selected from the group consisting of cadmium (Cd), sulfur (S), tellurium (Te), selenium (Se), zinc (Zn), indium (In), nitrogen (N), phosphorus (P), arsenic (As), antimony (Sb), aluminum (Al), gallium (Ga), lead (Pb), silicon (Si), germanium (Ge), and magnesium (Mg). Further, the QD may be a two-component core type, a three-component core type, a four-component core type, a core-shell type, or a core multi-shell type.

Note that, as described above, in the subpixel RSP, the light-emitting region RES is provided as the light-emitting region ES. In the light-emitting region RES, the EL layer 35 including the EML 353 that uses a red QD as a light-emitting material is formed as the EL layer 35 (in this case, the EL layer 35R). Further, the subpixel GSP is provided with the light-emitting region GES as the light-emitting region ES. In the light-emitting region GES, the EL layer 35 including the EML 353 that uses a green QD as a light-emitting material is formed as the EL layer 35. The subpixel BSP is provided with the light-emitting region BES as the light-emitting region ES. In the light-emitting region BES, the EL layer 35 including the EML 353 that uses a blue QD as a light-emitting material is formed as the EL layer 35.

The luminescent colors of the light-emitting regions ES provided in the same subpixel SP (in other words, the same light-emitting element LE) are all the same. Accordingly, the same subpixel SP includes the same kind of QD.

Therefore, the EML 353 may be formed in an island shape for each light-emitting region ES corresponding to each opening 32a, or may be formed in an island shape for each subpixel SP.

In either case, as described above, the light-emitting regions ES are formed in correspondence with each opening 32a of the bank 32 and, in the present embodiment, the bank 32 includes the plurality of openings 32a in each subpixel SP. Therefore, the EMLs 353 having the same luminescent color are formed in any of the openings 32a in the same subpixel SP.

Note that the layers other than the EML 353 included in the EL layer 35 may be formed into island shapes for each light-emitting region ES, may be formed into island shapes for each subpixel SP, or may be formed into solid shapes common to all subpixels SP. FIG. 3 illustrates an example in which each layer in the EL layer 35 is formed into an island shape for each subpixel SP.

The high-refractive-index material layer 37 and the low-refractive-index material layer 39 function as optical layers that refract light emitted from the EML 353, and also function as protection layers that protect the third electrode 36.

The high-refractive-index material layer 37 functions as a filling material that fills the recessed portion 36a of the third electrodes 36 in the opening 32a of the bank 32, and also functions as a protection layer that protects the EL layer 35 from an etching solution during the patterning of the auxiliary wiring line 38.

The high-refractive-index material layer 37 is formed at a position corresponding to the opening 32a of the bank 32 on the third electrode 36 in such a manner as to fill the recessed portion 36a in the opening 32a of the bank 32. In other words, the high-refractive-index material layer 37 is formed in the opening 32a of the bank 32, in which the second electrode 33, the EL layer 35, and the third electrode 36 are formed, in such a manner as to fill the interior of the opening 32a (strictly speaking, the interior of the recessed portion 36a of the third electrode 36).

Since the high-refractive-index material layer 37 is formed to fill the interior of the opening 32a (strictly speaking, the interior of the recessed portion 36a of the third electrodes 36), light reflected by the second electrode 33 covering the inclined face of the opening sidewall 32a1 of the bank 32 may be efficiently extracted to the outside.

The auxiliary wiring line 38 is formed adjacent to the high-refractive-index material layer 37 on the third electrode 36 in such a manner as to cover the peripheral edge portion of the high-refractive-index material layer 37 in the recessed portion 36a. As described above, the auxiliary wiring line 38 includes the plurality of openings 38a. These openings 38a are provided corresponding to the respective openings 32a of the bank 32. In other words, these openings 38a are provided corresponding to each recessed portion 36a of the third electrode 36, and are configured to expose the high-refractive-index material layer 37 provided in each recessed portion 36a from each of the openings 38a.

As illustrated in FIG. 4, the opening 38a is formed to be slightly smaller than the recessed portion 36a in a plan view. For this reason, the auxiliary wiring line 38 includes an opening 38a having an opening end (outer edge) on the high-refractive-index material layer 37 formed in an island shape so as to fill the interior of the recessed portion 36a. As illustrated in FIG. 3, the auxiliary wiring line 38 is formed in such a manner that a region (peripheral edge portion) of the auxiliary wiring line 38 surrounding the opening 38a overlaps the peripheral edge portion of the high-refractive-index material layer 37 formed in the island shape. The peripheral edge portion of the auxiliary wiring line 38 surrounding the opening 38a is disposed over the peripheral edge portion of the high-refractive-index material layer 37. To rephrase, the auxiliary wiring line 38 is disposed such that the peripheral edge portion of the auxiliary wiring line 38 surrounding the opening 38a covers the peripheral edge portion of the high-refractive-index material layer 37 in a plan view. Thus, in the present embodiment, the auxiliary wiring line 38 is disposed such that the lower face of the peripheral edge portion of the auxiliary line 38 surrounding the opening 38a is in contact with the upper face of the peripheral edge portion of the high-refractive-index material layer 37.

In this case, the peripheral edge portion of the high-refractive-index material layer 37 indicates an end portion (circumferential edge portion) of the high-refractive-index material layer 37 formed in an island shape so as to fill the recessed portion 36a. The peripheral edge portion of the auxiliary wiring line 38 surrounding the opening 38a indicates an end portion on the opening 38a side of the auxiliary wiring line 38 surrounding the opening 38a.

According to the present embodiment, since the EL layer 35 is covered with the high-refractive-index material layer 37 via the third electrode 36, it is possible to suppress or prevent the permeation of an etching solution into the EL layer 35 at the time of patterning the auxiliary wiring line 38. Further, as described above, since the peripheral edge portion of the auxiliary wiring line 38 surrounding the opening 38a covers the peripheral edge portion of the high-refractive-index material layer 37, it is also possible to suppress or prevent the permeation of the etching solution from the peripheral edge portion of the high-refractive-index material layer 37. Because of this, according to the present embodiment, it is possible to suppress or prevent a situation in which the etching solution at the time of patterning the auxiliary wiring line 38 permeates into the EL layer 35 and damages the EL layer 35. Thus, according to the present embodiment, it is possible to achieve both a reduction in resistance of the third electrode 36 by the formation of the auxiliary wiring line 38 and an improvement in light extraction efficiency.

As illustrated in FIG. 4, when an overlapping width between the peripheral edge portion of the auxiliary wiring line 38 surrounding the opening 38a and the peripheral edge portion of the high-refractive-index material layer 37 in a plan view is defined as d (μm), d is preferably 0.5 μm or more (where φ2>2×d). Further, d is more preferably 1.0 μm or more (where φ2>2×d). As a result, it is possible to more effectively suppress a situation in which the etching solution at the time of patterning the auxiliary wiring line 38 permeates into the EL layer 35 and damages the EL layer 35.

Note that d is the shortest distance between one end of the high-refractive-index material layer 37 and the opening end of the opening 38a in a portion where the peripheral edge portion of the auxiliary wiring line 38 surrounding the opening 38a covers the peripheral edge portion of the high-refractive-index material layer 37 in a plan view.

Further, when the shortest distance between the upper end and the lower end of a sidewall 36a1 (inclined face) of the recessed portion 36a of the third electrodes 36 in a plan view is defined as D (μm), a relation of d<D is preferred, and a relation of d≤¼×D is more preferred. D is substantially equal to (φ2−φ1)/2. Therefore, D can be paraphrased as (φ2−φ1)/2. By causing d to be less than D, from a region not covered with the auxiliary wiring line 38 on the opening sidewall 32a1 in a plan view, light reflected by the second electrode 33 provided in the above region can be extracted in a front direction. This makes it possible to efficiently utilize the second electrode 33 as a reflective layer on the opening sidewall 32a1.

In the present embodiment, with regard to D, a relation of 1 μm≤D≤22.5 μm is preferred, and a relation of 3 μm≤D≤8.5 μm is more preferred. Accordingly, with regard to d, specifically, a relation of d<5.6 μm is preferred, and a relation of d≤2.1 μm is more preferred.

As illustrated in FIG. 3 and FIG. 4, when the opening size (diameter) of the opening 38a of the auxiliary wiring line 38 is defined as φ3 (μm), φ3 satisfies a relation of φ3<φ2. Specifically, with regard to φ3, a relation of 17 μm≤φ3≤54 μm (where φ3<φ2) is preferred, and a relation of 19 μm≤φ3≤28 μm (where φ3<φ2) is more preferred.

The opening end of the opening 38a is located outside the lower end of the opening 32a of the bank in a plan view, that is, between the upper end and the lower end of the sidewall 36a1 (inclined face) of the recessed portion 36a of the third electrodes 36. With this, from a region not covered with the auxiliary wiring line 38 on the opening sidewall 32a1 in a plan view, light reflected by the second electrode 33 provided in the above region can be extracted in the front direction. This makes it possible to efficiently utilize the second electrode 33 as a reflective layer on the opening sidewall 32a1.

To prevent color mixing, the high-refractive-index material layer 37 is desirably formed in an island shape for each opening 32a of the bank 32.

The thickness of the high-refractive-index material layer 37 on the lower end of the opening 32a of the bank is desirably 1.0 μm or more, and is more desirably 2 μm or more. On the other hand, in a case where the high-refractive-index material layer 37 is too thick, it is difficult to achieve high resolution. Therefore, the thickness of the high-refractive-index material layer 37 is desirably less than 4 μm or less, and is more desirably 3 μm or less.

The low-refractive-index material layer 39 is formed over the third electrode 36 while being adjacent to the third electrode 36, the high-refractive-index material layer 37, and the auxiliary wiring line 38 in such a manner as to cover the high-refractive-index material layer 37 and the auxiliary wiring line 38. The low-refractive-index material layer 39 is a common layer provided in common to all the subpixels SP, covering the entire third electrode 36 and auxiliary wiring line 38 to protect the third electrode 36 and the auxiliary wiring line 38.

The high-refractive-index material layer 37 is formed of a material having a refractive index higher than that of the low-refractive-index material layer 39. As a result, part of light incident on the high-refractive-index material layer 37 can be reflected at an interface with the low-refractive-index material layer 39 and guided to the reflective surface formed on the bank 32, thereby contributing to an improvement in luminance in the front direction. That is, according to the present embodiment, by providing the high-refractive-index material layer 37 as described above, it is possible to efficiently utilize the second electrode 33 as the reflective layer on the opening sidewall 32a1.

On the other hand, the low-refractive-index material layer 39 is formed of a material having a refractive index lower than the refractive index of the high-refractive-index material layer 37. As described above, with the high-refractive-index material layer 37 formed in the opening 32a and with the low-refractive-index material layer 39 formed on the high-refractive-index material layer 37 while being adjacent to the high-refractive-index material layer 37, light from the EML 353 is totally reflected at the interface between the high-refractive-index material layer 37 and the low-refractive-index material layer 39 and directed toward the inclined face of the opening sidewall 32a1 of the opening 32a, thereby making it possible to extract the guided light component from the light extraction direction (front direction).

The refractive index of the high-refractive-index material layer 37 is not particularly limited as long as the index is higher than the refractive index of the low-refractive-index material layer 39, but is desirably 1.7 or greater, and more desirably 1.8 or greater. The refractive index of the high-refractive-index material layer 37 is preferred as the refractive index difference from the refractive index of the low-refractive-index material layer 39 can be increased, and the lower limit thereof is not particularly limited. However, when a large amount of an additive for improving the refractive index is included, there is a concern that a patterning performance may deteriorate. Therefore, the refractive index of the high-refractive-index material layer 37 is desirably 2.0 or less.

Examples of the high-refractive-index material used for forming the high-refractive-index material layer 37 include at least one organic insulating material selected from the group consisting of an acrylic resin, a siloxane-based resin, and materials obtained by adding an oxide to these resins.

The refractive index of the low-refractive-index material layer 39 is not particularly limited as long as the index is lower than the refractive index of the high-refractive-index material layer 37, but is desirably 1.4 or less, and more desirably 1.3 or less. The refractive index of the low-refractive-index material layer 39 is preferred as the refractive index difference from the refractive index of the high-refractive-index material layer 37 can be increased, and the upper limit thereof is not particularly limited. However, increasing a void space to reduce the refractive index raises reliability concerns. For this reason, the refractive index of the low-refractive-index material layer 39 is desirably 1.2 or greater.

Examples of the low-refractive-index material used for forming the low-refractive-index material layer 39 include a siloxane-based resin. As in the case of the high-refractive-index material layer 37, the low-refractive-index material layer 39 used may be one type or a combination of two or more types as appropriate. Note that, in the disclosure, the refractive index indicates an absolute refractive index in a visible light region.

Further, each of the high-refractive-index material layer 37 and the low-refractive-index material layer 39 may be a single layer or may have a layered structure. The thickness of the low-refractive-index material layer 39 is not particularly limited.

The sealing layer 4 is a layer that prevents penetration of foreign matters such as water or oxygen into the light-emitting element layer 3. As illustrated in FIG. 3, the sealing layer 4 includes, for example, an inorganic sealing film 41 covering the low-refractive-index material layer 39, an organic buffer film 42 in a layer above the inorganic sealing film 41, and an inorganic sealing film 43 in a layer above the organic buffer film 42.

The inorganic sealing film 41 and the inorganic sealing film 43 are light-transmissive inorganic insulating films and can be formed of inorganic insulating films such as silicon oxide films or silicon nitride films formed by CVD, for example. The organic buffer film 42 is a light-transmissive organic insulating film having a flattening effect and can be made of a coatable organic material such as acrylic. The organic buffer film 42 can be formed by, for example, ink-jet application, and a bank (not illustrated) for stopping droplets may be provided in the frame region NDA.

Note that materials and thicknesses of the thin film transistor layer 22, the second electrode 33, the EL layer 35, the third electrode 36, and the sealing layer 4 are not particularly limited, and may be similar to those in the related art.

The function layer 5, selected as appropriate depending on the application, is formed on the sealing layer 4. The function layer 5 may be a function film having at least one of an optical compensation function, a touch sensor function, and a protection function, or may be a glass substrate such as a touch panel, a polarizer, or a cover glass, for example.

### Method for Manufacturing Display Device 1

Next, a method for manufacturing the display device 1 described above will be described.

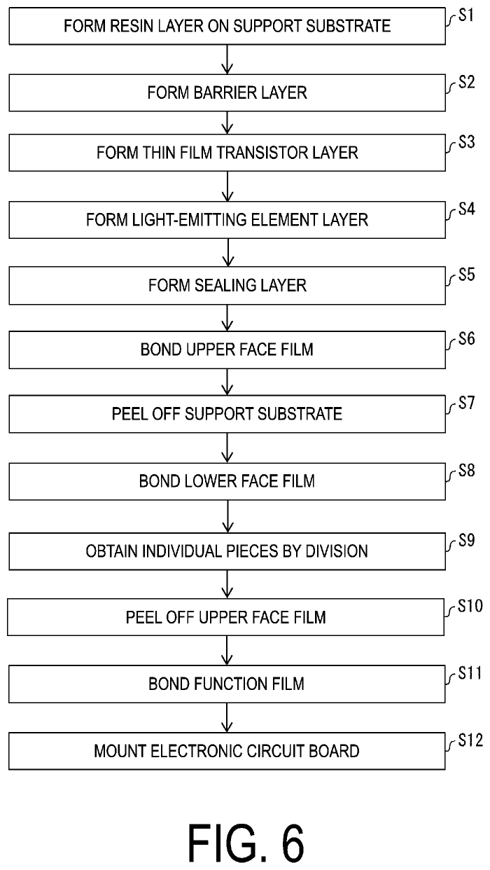

FIG. 6 is a flowchart illustrating an example of a manufacturing process of the display device 1 according to the present embodiment.

When a flexible display device is manufactured as the display device 1, first, a resin layer that is the insulating substrate 21 is formed on a light-transmissive support substrate (mother glass, for example; not illustrated), as illustrated in FIG. 6 (step S1). Next, a barrier layer is formed (step S2). Next, the thin film transistor layer 22 is formed (step S3). Next, the light-emitting element layer 3 is formed (step S4). Next, the sealing layer 4 is formed (step S5). Next, an upper face film for protection (not illustrated) is temporarily bonded onto the sealing layer 4 (step S6). Next, the support substrate is peeled from the resin layer through irradiation with laser light or the like (step S7). Next, a lower face film (not illustrated) is bonded to a lower face of the resin layer (step S8). Next, a layered body including the lower face film, the resin layer, the barrier layer, the thin film transistor layer 22, the light-emitting element layer 3, the sealing layer 4, and the upper face film is divided to obtain a plurality of individual pieces (step S9). Next, the upper face film is peeled from the obtained individual pieces (step S10), and a function film is bonded as the function layer 5 on the obtained individual pieces (step S11). Subsequently, an electronic circuit board (IC chip and FPC, for example; not illustrated) is mounted on a portion (of the frame region NDA; terminal portion TS) outward relative to the display region DA in which the plurality of pixels P (the plurality of subpixels SP) are formed (step S12). Note that steps S1 to S12 are performed by a display device manufacturing apparatus (including a film formation apparatus configured to perform each process of steps S1 to S5).

Note that the upper face film is bonded onto the sealing layer 4 as described above and functions as a support material when the support substrate is peeled off. Examples of the material of the upper face film include polyethylene terephthalate (PET). The lower face film is, for example, a PET film for achieving the display device 1 having excellent flexibility by being bonded to the lower face of the resin layer after the support substrate is peeled off. Note that the resin layer and the barrier layer are as described above.

Note that, although the above description describes the manufacturing method of the display device 1 having flexibility, ordinarily, processes such as formation of the resin layer and replacement of a base material are not required when the display device 1 not having flexibility is manufactured. Therefore, for example, when the display device 1 not having flexibility is to be manufactured, a process of layering including steps S2 to S5 is performed on a glass substrate, after which the process proceeds to step S9.

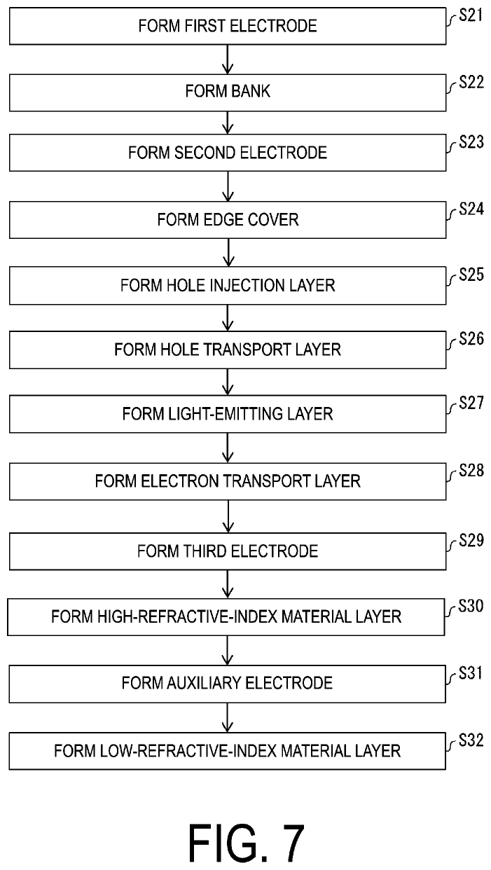

FIG. 7 is a flowchart illustrating an example of a formation process of the light-emitting element layer 3 indicated in step S4 in FIG. 6.

In the formation process of the light-emitting element layer 3, first, as illustrated in FIG. 7, the first electrode 31 is formed on the thin film transistor layer 22 (step S21). Next, the bank 32 is formed (step S22). Next, the second electrode 33 is formed (step S23). Next, the edge cover 34 is formed (step S24). Next, the HIL 351 (hole injection layer) is formed (step S25). Next, the HTL 352 (hole transport layer) is formed (step S26). Next, the EML 353 (light-emitting layer) is formed (step S27). Next, the ETL 354 (electron transport layer) is formed (step S28). Next, the third electrode 36 is formed (step S29). Next, the high-refractive-index material layer 37 is formed (step S30). Next, the auxiliary wiring line 38 is formed (step S31). Next, the low-refractive-index material layer 39 is formed (step S32).

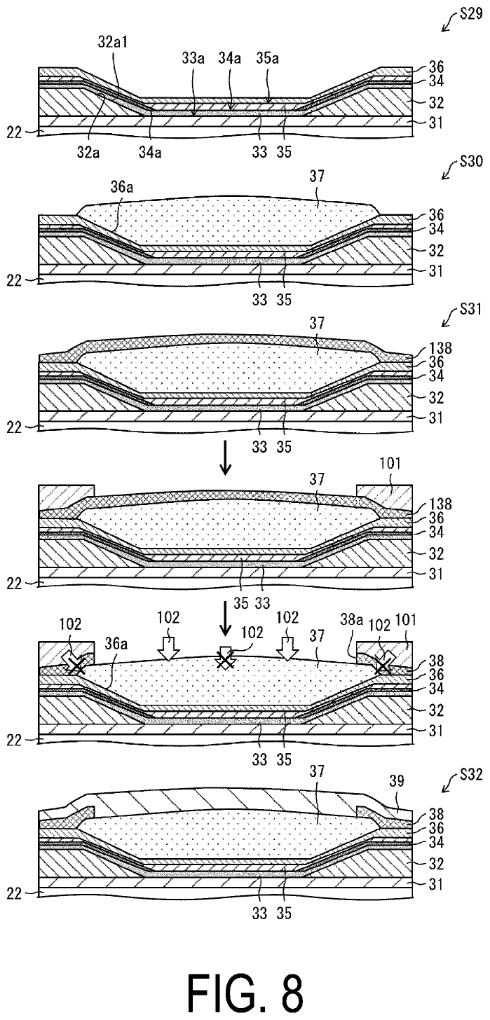

FIG. 8 is a cross-sectional view illustrating an example of a formation process of main portions of the light-emitting element layer 3 illustrated in FIG. 7. FIG. 8 illustrates the steps of S29 to S32 illustrated in FIG. 7. In FIG. 8, for convenience of illustration, the HIL 351, HTL 352, EML 353, and ETL 354 are not individually illustrated, but are collectively illustrated as the EL layer 35.

Note that the first electrode 31, the second electrode 33, and the third electrode 36 can be formed by, for example, physical vapor deposition (PVD) such as a sputtering method or a vacuum vapor deposition technique, a spin coating method, or an ink-jet method.

Further, the bank 32 and the edge cover 34 can be formed into a desired shape by, for example, using a photolithography method to pattern a layer formed of an insulating material deposited by PVD such as a sputtering method or a vacuum vapor deposition technique, a spin-coating method, or an ink-jet method.

In the present embodiment, as indicated by S29 in FIG. 8, the bank 32 is formed such that the bank 32 includes the opening 32a to expose the first electrode 31, and the opening 32a includes the opening sidewall 32a1 having a taper-shaped inclined face. Then, the second electrodes 33 having the recessed portion 33a, the edge cover 34 having the opening 34a, the EL layer 35 having the recessed portion 35a, and the third electrode 36 having the recessed portion 36a are formed in sequence in such a manner as to include the respective inclined faces along the opening sidewall 32a1 of the opening 32a.

For example, PVD such as a sputtering method or a vacuum vapor deposition technique, a spin coating method, or an ink-jet method is used for film formation of the HIL 351, the HTL 352, and the ETL 354.

When the EML 353 is the QD light-emitting layer as described above, first, for example, a lift-off template is formed in a region other than the formation region of the QD light-emitting layer (a non-formation region of the QD light-emitting layer to be formed) on the underlayer (the HIL 351 in the example illustrated in FIG. 5). Next, a QD dispersion including QDs and a solvent is applied onto the underlayer, and the template is peeled off. As a result, a desired QD light-emitting layer can be patterned in the region where the QD light-emitting layer is to be formed.

Note that the template can be formed by, for example, applying a resist for the template, pre-baking the resist, performing ultraviolet (UV) mask exposure, and developing the resist.

As described above, in a case in which the display device 1 includes, for example, the subpixel RSP, the subpixel GSP, and the subpixel BSP as the subpixels SP, QD light-emitting layers of three colors can be formed by repeating the processes from the formation of the template to the peeling of the template three times.

Note that, when the EML 353 is, for example, a light-emitting layer made of an organic light-emitting material, the EML 353 can be formed by, for example, a vacuum vapor deposition technique, a sputtering method, or an ink-jet method.

As indicated by S30 in FIG. 8, the high-refractive-index material layer 37 can be formed by applying the high-refractive-index material onto the third electrode 36 serving as the underlayer in such a manner as to fill the recessed portion 36a of the third electrode 36, pre-baking the material, performing UV mask exposure, developing the material, and then actually baking the material.

As indicated by S31 in FIG. 8, as for the auxiliary wiring line 38, first, a metal film 138 such as an Ag film to serve as the auxiliary wiring line 38 is formed on the third electrode 36 in such a manner as to cover the high-refractive-index material layer 37. Subsequently, a photoresist is film-formed on the metal film 138, pattern-exposed, and then developed. With this, a photoresist pattern 101 made of the photoresist is formed covering a non-removal portion of the metal film 138. Then, the metal film 138 is patterned by dropping an etching solution 102 using the photoresist pattern 101 as a mask. As a result, the auxiliary wiring line 38 is formed that is made of the metal film 138, includes the opening 38a corresponding to the recessed portion 36a of the third electrode 36, and covers only the peripheral edge portion of the high-refractive-index material layers 37 filled in the interior of the recessed portion 36a. In this case, the expression that the auxiliary wiring line 38 covers only the peripheral edge portion of the high-refractive-index material layer 37 means that the peripheral edge portion of the auxiliary wiring line 38 surrounding the opening 38a covers the peripheral edge portion of the high-refractive-index material layer 37 as described above.

As the etching solution 102, an acidic etching solution capable of dissolving metal is used.

In the present embodiment, as described above, the high-refractive-index material layer 37 is formed before the metal film 138 is patterned. Accordingly, since the EL layer 35 is covered with the high-refractive-index material layer 37 via the third electrode 36, it is possible to suppress or prevent the permeation of the etching solution 102 into the EL layer 35 at the time of patterning the auxiliary wiring line 38. Further, as described above, since the peripheral edge portion of the auxiliary wiring line 38 surrounding the opening 38a covers the peripheral edge portion of the high-refractive-index material layer 37, it is also possible to suppress or prevent the permeation of the etching solution 102 from the peripheral edge portion of the high-refractive-index material layer 37. Thus, according to the present embodiment, it is possible to suppress or prevent a situation in which the EL layer 35 is damaged by the etching solution 102.

Then, after the photoresist pattern 101 is removed using a resist solvent, the low-refractive-index material layer 39 is formed on the third electrode 36 to cover the high-refractive-index material layer 37 and the auxiliary wiring line 38, as indicated by S32 in FIG. 8.

For the application of the high-refractive-index material layer 37 and the formation of the low-refractive-index material layer 39, for example, a vacuum vapor deposition technique, a spin coating method, or an ink-jet method may be used.

Note that, in the above description, a case in which the lift-off template is used only for forming the EML 353 is described as an example. However, the present embodiment is not limited thereto, and the lift-off template may also be used to form layers other than the EML 353 of the EL layer 35.

### Advantageous Effects

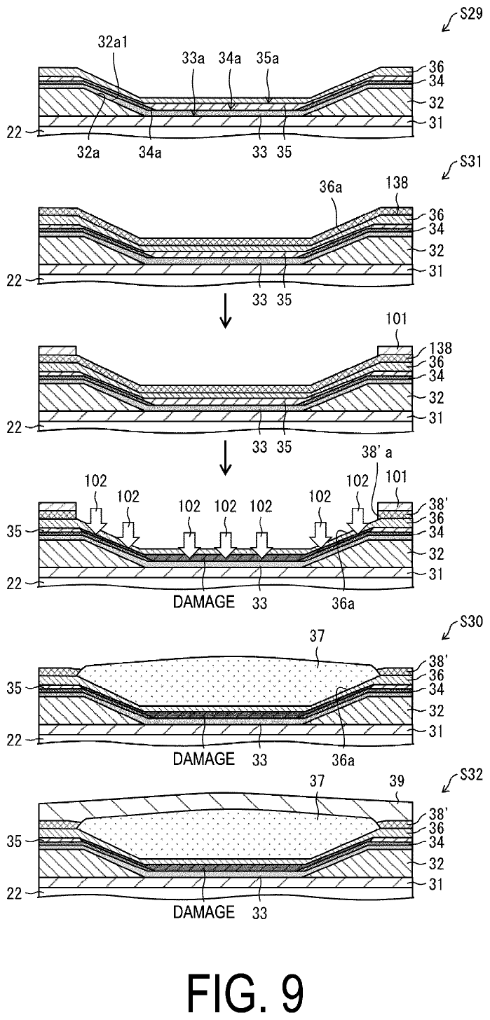

Next, advantageous effects of the display device 1 according to the present embodiment will be described below with reference to FIG. 9 to FIG. 11.

FIG. 9 is a cross-sectional view illustrating an example of a formation process of main portions of the light-emitting element layer 3 when a known method for forming an auxiliary wiring line on an upper layer electrode is applied to the manufacturing method for the display device 1 according to the present embodiment. FIG. 9 illustrates an example in which step S31 is performed after step S29, and thereafter step S30 and step S32 are performed.

Therefore, in FIG. 9, after step S29, the metal film 138 such as an Ag film is formed on the third electrode 36 to cover the entire third electrode 36. In this case, the metal film 138 including a recessed portion along the recessed portion 36a of the third electrode 36 is formed on the third electrode 36. Thereafter, a photoresist is film-formed on the metal film 138, pattern-exposed, and then developed. With this, the photoresist pattern 101 made of the photoresist is formed covering a non-removal portion of the metal film 138. Then, the metal film 138 is patterned by dropping the etching solution 102 using the photoresist pattern 101 as a mask. As a result, an auxiliary wiring line 38′ is formed that is made of the metal film 138 and includes an opening 38a′ corresponding to the recessed portion 36a of the third electrode 36.

At this time, in the example illustrated in FIG. 9, since the high-refractive-index material layer 37 is not formed in the recessed portion 36a, the etching solution 102 permeates into the EL layer 35 and damages the EL layer 35.

Then, after the photoresist pattern 101 is removed using a resist solvent, the high-refractive-index material layer 37 is formed on the third electrode 36 exposed from the opening 38′ of the auxiliary wiring line 38′ in such a manner as to fill the recessed portion 36a of the third electrodes 36, as indicated by S30 in FIG. 9. Accordingly, in this case, the peripheral edge portion of the high-refractive-index material layer 37 is formed in contact with a sidewall of the opening 38a′ or the upper face of the peripheral edge portion surrounding the opening 38a′ in the auxiliary wiring line 38′.

Subsequently, as indicated by S32 in FIG. 9, the low-refractive-index material layer 39 is formed on the third electrode 36 to cover the high-refractive-index material layer 37 and the auxiliary wiring line 38′.

As described above, in the case where the EL layer 35 is not covered with the high-refractive-index material layer 37 when the auxiliary wiring line 38′ is patterned, the EL layer 35 is damaged by the etching solution 102. Because of this, even in a case where, by forming the auxiliary wiring line 38′, the IR drop can be suppressed by the auxiliary wiring line 38′, the luminous efficiency decreases due to the damage described above. Accordingly, in this case, it is not possible to achieve both a reduction in the resistance of the third electrode 36 by the formation of the auxiliary wiring line 38′ and an improvement in the light extraction efficiency.

In contrast, according to the present embodiment, as described above, the high-refractive-index material layer 37 is formed before the metal film 138 is patterned. In addition, the peripheral edge portion of the auxiliary wiring line 38 surrounding the opening 38a covers the peripheral edge portion of the high-refractive-index material layer 37. Thus, it is possible to achieve both a reduction in the resistance of the third electrode 36 by the formation of the auxiliary wiring line 38 and an improvement in the light extraction efficiency.

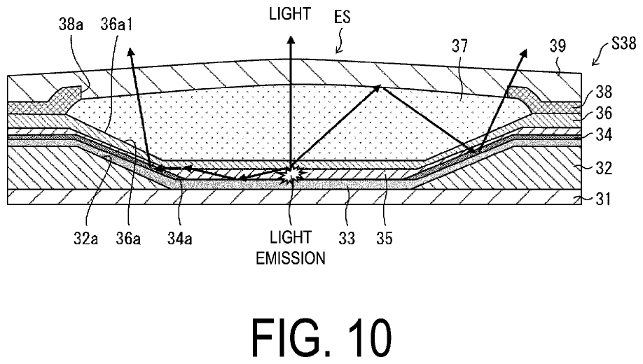

FIG. 10 is a cross-sectional view illustrating an optical path of light in the light-emitting region ES of the light-emitting element layer 3 of the display device 1 according to the present embodiment.

As described above, the display device 1 according to the present embodiment includes the bank 32 provided with the opening 32a including the opening sidewall 32a1 that is inclined (specifically the opening sidewall 32a1 provided with the inclined face having a tapered shape), the second electrode 33 formed on the bank 32, closing the opening 32a, the third electrode 36 formed above the second electrode 33, and the EL layer 35 including at least the EML 353 and formed between the second electrode 33 and the third electrode 36, adjacently to the second electrode 33 and the third electrode 36. The second electrode 33 is provided with an inclined face formed on the opening sidewall 32a1 along the opening sidewall 32a1. The EL layer 35 is provided with an inclined face formed on the inclined face of the second electrode 33 along the inclined face of the second electrode 33. The third electrode 36 is provided with an inclined face, as the sidewall 36a1 of the recessed portion 36a, formed on the inclined face of the EL layer 35 along the inclined face of the EL layer 35.

In such a display device 1, when a current equal to or greater than a light emission threshold current is supplied between the second electrode 33 and the third electrode 36, the EML 353 therebetween emits light. Of the light emitted from the EML 353, light incident on the third electrode 36 at an angle (incident angle) smaller than a total reflection angle (critical angle) travels through the third electrode 36, the high-refractive-index material layer 37, and the low-refractive-index material layer 39, and is released to the outside from the opening 38a of the auxiliary wiring line 38 in the light extraction direction (front direction) of the display device 1.

On the other hand, of the light emitted from the EML 353, light incident on an interface between the EL layer 35 and the third electrode 36 at an angle (incident angle) equal to or larger than the total reflection angle (critical angle) is totally reflected at the interface. The light totally reflected at the interface between the EL layer 35 and the third electrode 36 propagates inside the EL layer 35 in an in-plane direction thereof while being reflected at the interface between the second electrode 33 and the EL layer 35 and the interface between the third electrode 36 and the EL layer 35 in the opening 32a of the bank 32. Then, when the light propagating inside the EL layer 35 reaches the inclined face of the second electrode 33 formed on the opening sidewall 32a1 of the opening 32a, the light is reflected at the inclined face and is emitted from the opening 38a of the auxiliary wiring line 38 to the outside in the light extraction direction (front direction) of the display device 1 via the third electrode 36, the high-refractive-index material layer 37, and the low-refractive-index material layer 39.

In the present embodiment, as described above, the high-refractive-index material layer 37 is formed in the opening 32a of the bank 32 (more strictly, in the opening 36a of the third electrodes 36 in the opening 32a). Further, on the high-refractive-index material layer 37, the low-refractive-index material layer 39 is formed adjacent to the high-refractive-index material layer 37. Because of this, light incident on the interface between the high-refractive-index material layer 37 and the low-refractive-index material layer 39 at an incident angle equal to or larger than the critical angle is totally reflected and directed toward the inclined face of the opening sidewall 32a1 of the opening 32a, and the guided light component thereof can be extracted from the light extraction direction (front direction).

In the present embodiment, the second electrode 33 is formed on the opening sidewall 32a1 of the opening 32a. The second electrode 33 formed on the opening sidewall 32a1 functions as a reflective layer. Accordingly, as described above, it is possible to reflect the light (guided light component) propagating (guided) through the EL layer 35 toward the opening sidewall 32a1 by the total reflection and the light reflected at the interface between the high-refractive-index material layer 37 and the low-refractive-index material layer 39. As discussed above, in the present embodiment, the light is reflected by the second electrode 33 as a reflective layer (in other words, the inclined face of the second electrode 33 serving as a reflective surface) provided on the opening sidewall 32a1, and can be extracted to the outside in the light extraction direction (front direction) of the display device 1.

Thus, according to the present embodiment, it is possible to provide a light-emitting device capable of improving the light extraction efficiency and suppressing the damage of the EL layer due to the permeation of an etching solution used for patterning the auxiliary wiring line, compared to the related art.

Further, according to the present embodiment, the opening 32a of the bank 32 has the small hole shape described above, in particular, the inclination angle (θ) described above, the opening size (φ1) on the upper side of the bank 32 described above, the opening size on the lower side of the bank 32 described above, the height (h) of the bank 32 described above, and the like, thereby making it possible to efficiently extract the guided light component to the outside.

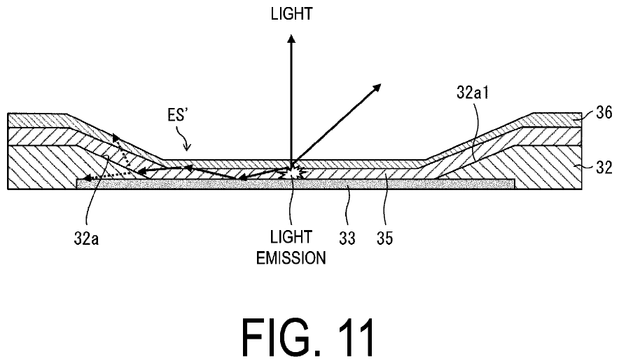

Meanwhile, FIG. 11 is a cross-sectional view illustrating an optical path of light in a light-emitting region ES′ of a known light-emitting element as described in PTL 1.

As illustrated in FIG. 11, in a case where the second electrode 33 is not formed on the opening sidewall 32a1 of the opening 32a, of the light emitted from the EML 353, the light (guided light component) propagating (guided) toward the opening sidewall 32a1 inside the EL layer 35 by the total reflection cannot be efficiently extracted in the front direction of the display device 1.

In a case where none of the high-refractive-index material layer 37 and the low-refractive-index material layer 39 are formed, it is not possible to totally reflect the light incident on the interface between the high-refractive-index material layer 37 and the low-refractive-index material layer 39 at an incident angle equal to or larger than the critical angle and extract the guided light component thereof from the front direction of the display device 1.

In the structure illustrated in FIG. 11, the guided light that is not extracted in the front direction hits the opening sidewall 32a1 of the bank 32, whereby only a small amount of light can be extracted.

Accordingly, according to the present embodiment, as described above, it is possible to provide a light-emitting device capable of improving light extraction efficiency and suppressing an increase in drive voltage compared to the related art.

### Second Embodiment

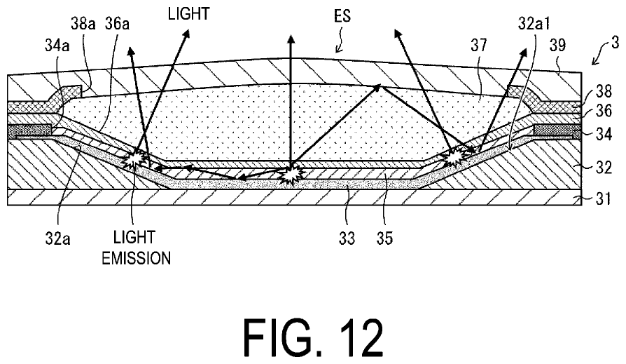

Another embodiment of the disclosure will be described below mainly based on FIG. 12. Note that, for convenience of description, members having the same functions as those of the members described in the previous embodiment will be denoted by the same reference numerals and signs, and descriptions thereof will not be repeated.

FIG. 12 is a cross-sectional view illustrating a schematic configuration of main portions of a light-emitting element layer 3 of a display device 1 according to the present embodiment, together with an optical path of light in a light-emitting region.

The display device 1 according to the present embodiment is the same as the display device 1 according to the first embodiment except for the following point.

The display device 1 according to the present embodiment has a configuration in which an opening 34a of an edge cover 34 is formed corresponding to each of openings 32a of a bank 32 to open each opening 32a.

The edge cover 34 according to the present embodiment is formed on the bank 32 provided with a second electrode 33 in such a manner as to cover the upper face of the bank 32 and a portion of the second electrode 33 located on the upper face of the bank 32. A portion of the second electrode 33 covering the bottom face of a recessed portion 33a and the opening 32a of the bank 32 is not covered with the edge cover 34 and is exposed from the openings 34a of the edge cover 34.

In the present embodiment, as described above, the openings 34a corresponding to each opening 32a of the bank 32 is formed in the edge cover 34, whereby the opening size of the opening 34a of the edge cover 34 is equal to an opening size (φ2) at the upper side of the bank. Therefore, the opening size (diameter) of the edge cover 34 according to the present embodiment is preferably in a range from 12 μm to 65 μm and larger than an opening size (φ1) at the lower side of the bank, and is also preferably in a range from 18 μm to 32 μm and larger than the opening size (φ1) at the lower side of the bank.

In the present embodiment, as illustrated in FIG. 12, the edge cover 34 does not cover a portion of the second electrode 33 located on an opening sidewall 32a1. In the present embodiment as well, as in the first embodiment, an auxiliary wiring line having the same outer shape as the second electrode 33 and provided with an opening 38a corresponding to each opening 32a is used for an auxiliary wiring line 38.

Further, also in the present embodiment, an insulating edge cover having transparency may be used for the edge cover 34.

In the present embodiment, a portion of the second electrode 33 located on the opening sidewall 32a1 is not covered with the edge cover 34, and thus the second electrode 33 formed on the opening sidewall 32a1 of the bank 32 functions as a reflective layer and also functions as an electrode.

As described above, in the present embodiment, since the second electrode 33 itself formed on the opening sidewall 32a1 also functions as an electrode, it is possible for the EML 353 to emit light on the opening sidewall 32a1 as well, as illustrated in FIG. 12. Therefore, a portion on the opening sidewall 32a1 of the bank 32 can also be utilized as a light-emitting portion, and the light-emitting area can be increased and the light extraction efficiency can be improved as compared with a case in which an electrode capable of supplying a current to an EL layer 35 is not formed on the opening sidewall 32a1 of the bank 32.

Here, the case where an electrode capable of supplying a current to the EL layer 35 is not formed on the opening sidewall 32a1 of the bank 32 includes the following (1) and (2):
(1) A case where the second electrode 33 is not formed on the opening sidewall 32a1 of the bank 32; and
(2) A case where, even if the second electrode 33 is formed on the opening sidewall 32a1 of the bank 32, the second electrode 33 on the opening sidewall 32a1 of the bank 32 is covered with an insulating layer such as the edge cover 34 and does not function as an electrode as in the first embodiment.

According to the present embodiment, the second electrode 33 itself formed on the opening sidewall 32a1 of the opening 32a also functions as an electrode, thereby making it possible to increase the electrode area. This makes it possible to suppress a rise in the drive voltage caused by the opening 32a of the bank 32 having the small hole shape described in the first embodiment.

### Third Embodiment

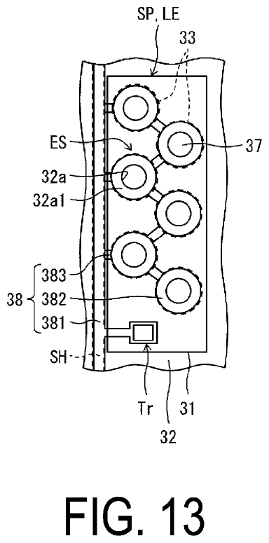

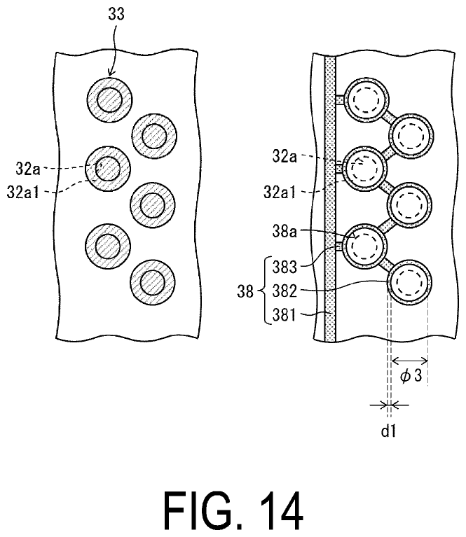

A description of still another embodiment of the disclosure will be given below mainly based on FIG. 13 and FIG. 14. Note that, for convenience of description, members having the same functions as those of the members described in the above-described embodiments will be denoted by the same reference numerals and signs, and descriptions thereof will not be repeated.

FIG. 13 is a plan view illustrating an example of a schematic configuration of main portions of a display device 1 according to the present embodiment, as viewed from above an auxiliary wiring line 38 of a subpixel SP of the display device 1. FIG. 14 is a plan view in which a second electrode 33 and the auxiliary wiring line 38 of the subpixel SP in the display device 1 according to the present embodiment are illustrated side by side. In FIG. 14, an opening 32a of a bank 32 is indicated by a dotted line in order to indicate a relationship between the opening 32a, and a recessed portion 33a (trench portion) of the second electrode 33 and an opening 38a of the auxiliary wiring line 38.

The display device 1 according to the present embodiment is the same as the display devices 1 according to the first and second embodiments except for the following point.

In the present embodiment, the second electrodes 33 are formed in an island shape for each light-emitting region ES (in other words, for each opening 32a) as illustrated in FIG. 13 and FIG. 14, for example, in such a manner as to overlap a portion of a first electrode 31 in each subpixel SP. Thus, the plurality of second electrodes 33 are provided in each subpixel SP.

In the present embodiment, the second electrode 33 is patterned in such an appropriate manner that the second electrode 33 is formed only in the opening 32a of the bank 32 including the opening sidewall 32a1 having an inclined face, for example. An edge of each second electrode 33 is located on the upper face of the bank 32.

The auxiliary wiring line 38 includes a trunk line portion 381, a frame-shaped portion 382 having an opening 38a and covering the peripheral edge portion of a high-refractive-index material layer 37 in a frame shape along the peripheral edge portion thereof in a plan view, and a branch line portion 383 electrically connecting the trunk line portion 381 and the frame-shaped portion 382.

In the example illustrated in FIG. 13 and FIG. 14, the opening 32a of the bank 32 is formed in a circular shape in a plan view, and the high-refractive-index material layers 37 and the second electrode 33 are formed in a circular shape inside the opening 32a. Thus, the frame-shaped portion 382 is formed in a ring shape that surrounds the opening 32a of the bank 32 and covers edges of the high-refractive-index material layer 37 and the second electrode 33.

In the present embodiment, an edge cover 34 may be formed on the bank 32 to cover the upper face of the bank 32 and an edge of each second electrode 33 or a portion formed on an opening sidewall 32a1. The edge cover 34 may be formed on the bank 32 to cover the upper face of the bank 32 and to surround the edge of each second electrode 33. The frame-shaped portion 382 may be formed to surround an opening 34a of the edge cover 34.

It is sufficient for the branch line portion 383 to be formed to be able to electrically connect the trunk line portion 381 and the frame-shaped portion 382. Accordingly, as illustrated in FIG. 13 and FIG. 14, the branch line portion 383 may be formed to couple the trunk line portion 381 and the frame-shaped portion 382, or may be formed to couple the frame-shaped portion 382 electrically connected to the trunk line portion 381 and another frame-shaped portion 382.

In the present embodiment, a transparent electrode is used for the first electrode 31.

According to the present embodiment, unwanted reflection of the display device 1 may be suppressed by forming the first electrode 31, the second electrode 33, and the auxiliary wiring line 38 in the manner described above.

### Fourth Embodiment

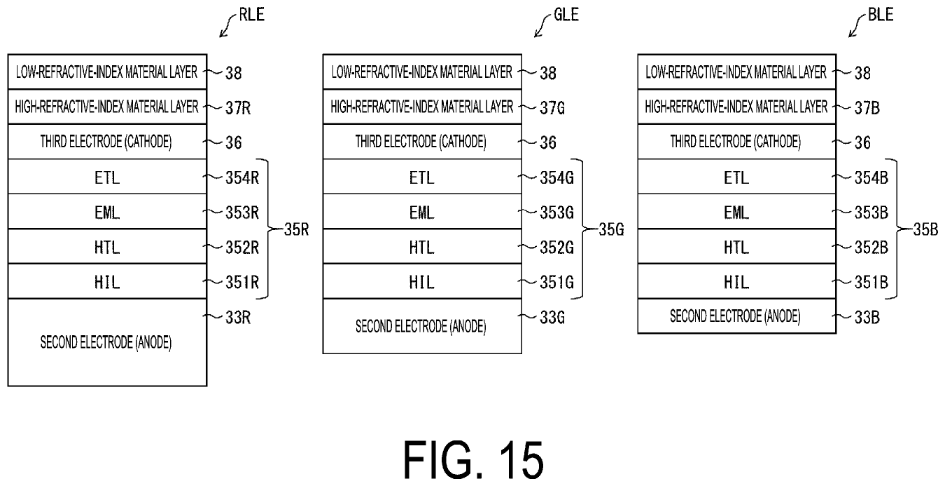

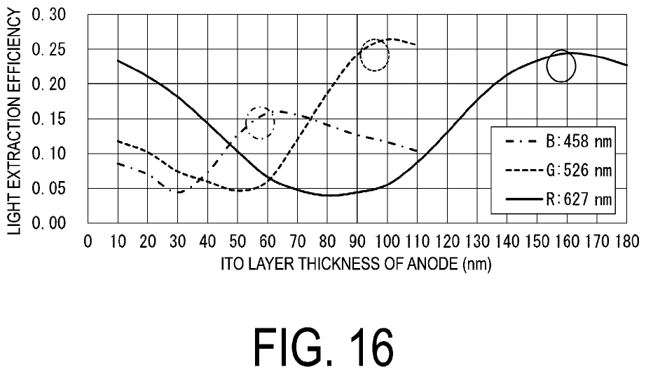

A description of still another embodiment of the disclosure will be described below mainly based on FIG. 15 and FIG. 16. Note that, for convenience of description, members having the same functions as those of the members described in the above-described embodiments will be denoted by the same reference numerals and signs, and descriptions thereof will not be repeated.

FIG. 15 is a diagram schematically illustrating an example of a layered structure in respective light-emitting regions (light-emitting region RES, light-emitting region GES, and light-emitting region BES) of light-emitting elements LE of respective colors (light-emitting element RLE, light-emitting element GLE, and light-emitting element BLE) in a display device 1 according to the present embodiment. FIG. 15 also illustrates, as an example, a case in which the display device 1 is a top-emitting type display device having a known structure, but the display device 1 according to the present embodiment is not limited thereto.

The display device 1 according to the present embodiment is the same as the display devices 1 according to the first to third embodiments except that film thicknesses of anodes serving as optical distance adjustment layers in respective subpixels SP are different from one another. In the present embodiment, a layered body obtained by layering, for example, an Ag alloy containing Ag and ITO in the order of ITO/Ag alloy/ITO from the lower layer side is used for a second electrode 33. In the present embodiment, a layer thickness of the ITO (light-transmissive electrode) on the Ag alloy (reflective electrode) of the second electrode 33 is changed for each subpixel SP (in other words, for each light-emitting element LE).

The effect of the microcavity structure applied in the OLED can be obtained by optimally designing the layer thicknesses of the layers between the anode reflective electrode and the cathode translucent electrode or the like. However, the layer thickness of an EL layer (HTL, for example) or the like other than the light-emitting layer also needs to be changed in accordance with the luminescent color of the OLED. Further, there is a possibility that a carrier balance changes due to a change in the layer thickness of each EL layer, thereby making the optimized design overly complex.

On the other hand, when the anode film thickness of the QLED is designed with the light extraction efficiency optimized in accordance with the luminescent color of the QLED as in the present embodiment, the carrier balance in the QLED does not change. Therefore, in this case, the light extraction efficiency can be improved by a layer structure (layer thickness of each EL layer) with an optimized carrier balance.

In the example illustrated in FIG. 15, in a top-emitting type display device 1 having a known structure, the second electrode 33 of the light-emitting element LE of each color of the subpixel SP of each color, which is the anode, has a layered structure of a reflective electrode and a light-transmissive electrode. Then, the figure illustrates, as an example, a case in which the layer thickness of the light-transmissive electrode of the second electrode 33 of each light-emitting element LE is changed for each subpixel SP (in other words, for each light-emitting element LE of each color) in order to maximize the light extraction efficiency in each light-emitting region ES of the light-emitting element LE of each subpixel SP.

As illustrated in FIG. 15, the light-emitting element RLE includes, for example, a second electrode 33R, an EL layer 35R, a third electrode 36, a high-refractive-index material layer 37R, and a low-refractive-index material layer 39 in this order from the lower layer side in each light-emitting region RES. The EL layer 35R includes, for example, an HIL 351R, HTL 352R, EML 353R, and ETL 354R in this order from the lower layer side.

The light-emitting element GLE includes, for example, a second electrode 33G, an EL layer 35G, the third electrode 36, a high-refractive-index material layer 37G, and the low-refractive-index material layer 39 in this order from the lower layer side in each light-emitting region GES. The EL layer 35G includes, for example, an HIL 351G, HTL 352G, EML 353G, and ETL 354G in this order from the lower layer side.

The light-emitting element BLE includes, for example, a second electrode 33B, an EL layer 35B, the third electrode 36, a high-refractive-index material layer 37B, and the low-refractive-index material layer 39 in this order from the lower layer side in each light-emitting region BES. The EL layer 35B includes, for example, an HIL 351B, HTL 352B, EML 353B, and ETL 354B in this order from the lower layer side.

FIG. 16 is a graph showing a relationship between a layer thickness of ITO on the reflective electrode and light extraction efficiency at the respective anodes (i.e., second electrode 33R, second electrode 33G, and second electrode 33B) in each light-emitting region ES of the light-emitting elements LE of respective colors.

In the present embodiment, the layer thickness of the light-transmissive electrode (ITO) on the reflective electrode of the anode of the light-emitting element LE of each color is selected with reference to the result of an optical simulation shown in FIG. 16. At this time, as the layer thickness of the light-transmissive electrode (ITO), a desired layer thickness was selected such that the light extraction efficiency in each light-emitting region ES of the light-emitting element LE of each color was maximized.

In the layered structure in the simulation, the PEDOT:PSS for the HIL 351R, the HIL 351G, and the HIL 351B was set at a layer thickness of 40 nm. For the HTL 352R, the HTL 352G and the HTL 352B, the TFB was set at a layer thickness of 35 nm. In the EML 353R, the red QDs were set at a layer thickness of 30 nm. In the EML 353G, the green QDs were set at a layer thickness of 30 nm. In the EML 353B, the blue QDs were set at a layer thickness of 30 nm. For the ETL 354R, the ETL 354G, and the ETL 354B, ZnO was set at a layer thickness of 50 nm. The third electrode 36 was formed of ITO at a layer thickness of 100 nm.

Note that, in this simulation, to simplify calculation, the bank structure was not set, and the high-refractive-index material and the low-refractive-index material were omitted.

From the results shown in FIG. 16, in the present embodiment, the layer thickness of the light-transmissive electrode on the reflective electrode of the second electrode 33 was set to satisfy a relation of the layer thickness of the light-transmissive electrode of the second electrode 33R>the layer thickness of the light-transmissive electrode of the second electrode 33G>the layer thickness of the light-transmissive electrode of the second electrode 33B.

Specifically, as described above, the second electrode 33 had a layered structure (three-layer structure) of ITO/Ag/ITO. Then, in the light-emitting region RES of the subpixel RSP, the layer thickness of the ITO positioned on the Ag electrode of the reflective electrode in the second electrode 33R (that is, layer thickness of the ITO positioned between the reflective electrode of the second electrode 33R and the third electrode 36) was set to 160 nm.

In the light-emitting region GES of the subpixel GSP, the layer thickness of the ITO positioned on the Ag electrode of the reflective electrode in the second electrode 33G (that is, layer thickness of the ITO positioned between the reflective electrode of the second electrode 33G and the third electrode 36) was set to 100 nm.

In the light-emitting region BES of the subpixel BSP, the layer thickness of the ITO positioned on the Ag electrode of the reflective electrode in the second electrode 33B (that is, layer thickness of the ITO positioned between the reflective electrode of the second electrode 33B and the third electrode 36) was set to 65 nm.

Further, from the HIL 351 to the ITO of the third electrode 36, the layers were formed at the same layer thickness using the same materials as those in the simulation. Specifically, PEDOT:PSS was formed for the HIL 351R, the HIL 351G, and the HIL 351B at a layer thickness of 40 nm. TFB was formed for the HTL 352R, the HTL 352G, and the HTL 352B at a layer thickness of 35 nm. In the EML 353R, red QDs were formed at a layer thickness of 30 nm. In the EML 353G, green QDs were formed at a layer thickness of 30 nm. In the EML 353B, blue QDs were formed at a layer thickness of 30 nm. For the ETL 354R, the ETL 354G, and the ETL 354B, ZnO was formed at a layer thickness of 50 nm. The third electrode 36 was formed of ITO at a layer thickness of 100 nm. The high-refractive-index material layer 37 was formed at a layer thickness of 2 μm on the lower ends of the openings 32a of the bank 32, filling the recesses (trench portions) of the third electrode 36 in the formation region of the bank 32. The low-refractive-index material layer 39 was formed at a layer thickness (design value) of 350 nm.

According to the present embodiment, the layer thickness of the light-transmissive electrode of the second electrode 33R, the layer thickness of the light-transmissive electrode of the second electrode 33G, and the layer thickness of the light-transmissive electrode of the second electrode 33B were set as described above, thereby making it possible to improve the light extraction efficiencies of the light-emitting region RES, the light-emitting region GES, and the light-emitting region BES.

Note that, in the present embodiment, a case in which the layer thicknesses of the light-transmissive electrodes on the reflective electrode of the respective second electrodes 33 differ from one another in the subpixel RSP, the subpixel GSP, and the subpixel BSP has been described as an example. In the present embodiment, as described above, the layer thicknesses of the light-transmissive electrodes decrease in the order of the layer thickness of the light-transmissive electrode of the second electrode 33R, the layer thickness of the light-transmissive electrode of the second electrode 33G, and the layer thickness of the light-transmissive electrode of the second electrode 33B. However, if the device structure is changed, the thickness relationship is not limited thereto. Depending on the device structure, the relationship between layer thicknesses of the light-transmissive electrodes may vary.

For example, the layer thickness of the light-transmissive electrode in one subpixel SP among the subpixel RSP, the subpixel GSP, and the subpixel BSP may differ from the layer thickness of the light-transmissive electrodes in the remaining two subpixels SP.

Accordingly, in the second electrodes 33, the layer thicknesses of the light-transmissive electrodes described above may differ from each other in at least two subpixels SP among the subpixel RSP, the subpixel GSP, and the subpixel BSP. That is, when the layer thicknesses of the light-transmissive electrodes on the reflective electrodes of the second electrodes 33 are compared between at least two selected subpixels SP, the layer thicknesses of the light-transmissive electrodes may differ from each other. In other words, the layer thickness of the light-transmissive electrode of at least one subpixel SP among the subpixel RSP, the subpixel GSP, and the subpixel BSP may differ from the layer thickness of the light-transmissive electrodes of the other subpixels SP. As discussed above, the light-transmissive electrodes of the second electrodes 33 may have at least two different thicknesses.

### Fifth Embodiment

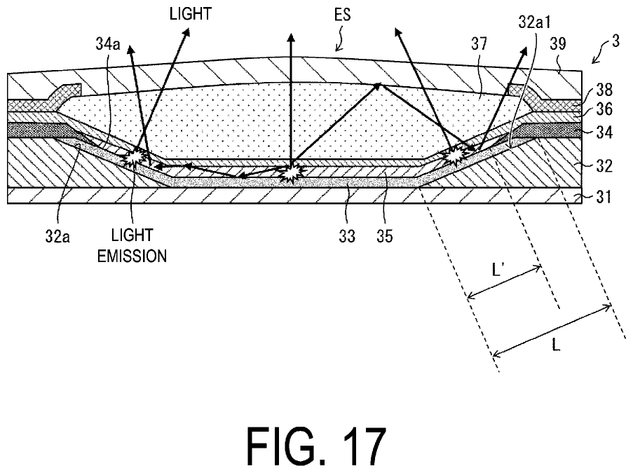

A description of still another embodiment of the disclosure will be described below mainly based on FIG. 17. Note that, for convenience of description, members having the same functions as those of the members described in the above-described embodiments will be denoted by the same reference numerals and signs, and descriptions thereof will not be repeated.

FIG. 17 is a cross-sectional view illustrating a schematic configuration of main portions of a light-emitting element layer 3 of a display device 1 according to the present embodiment, together with an optical path of light in a light-emitting region ES in the light-emitting element layer 3.

In the present embodiment, for example, as illustrated in FIG. 17, a second electrode 33 is patterned in such a manner as to form the second electrode 33 only in an opening 32a of a bank 32 including an opening sidewall 32a1 having an inclined face, and also form an end portion (opening end) of an opening 34a of an edge cover 34 on the opening sidewall 32a1.

In the present embodiment, a portion of the second electrode 33 on the opening sidewall 32a1 (that is, a portion of the inclined face of the second electrode 33) is covered with the edge cover 34. Therefore, the EL layer 35 is provided with an inclined face in a portion on the opening sidewall 32a1 along a portion of the inclined face of the second electrode 33 (that is, a portion of the inclined face of the second electrode 33 not covered with the edge cover 34). Further, the third electrode 36 is provided with an inclined face in a portion on the opening sidewall 32a1 along the inclined face of the EL layer 35 along the inclined face of the second electrode 33.

The display device 1 according to the present embodiment is the same as the display devices 1 according to the first to fourth embodiments except for these points.

In the present embodiment, when L is defined as a length of the opening sidewall 32a1 of the bank 32 and L′ is defined as a length of a portion of the opening sidewall 32a1 not covered with the edge cover 34, the edge cover 34 is patterned by, for example, photolithography, positioning the end portion of the opening 34a of the edge cover 34 at a position where the L′is longer than ⅓L and shorter than ⅔L. That is, in the present embodiment, the edge cover 34 is formed to satisfy ⅓L<L′<⅔L.

Note that the length (L) of the opening sidewall 32a1 of the bank 32 indicates a length connecting the upper end and the lower end of the opening sidewall 32a1 of the bank 32 at the shortest distance along the surface of the opening sidewall 32a1. Further, the lower end of the opening sidewall 32a1 of the bank 32 refers to an end portion of the opening 34a of the bank 32 on the first electrode 31 side (lower side that is an array substrate 2 side). An upper end of the opening sidewall 32a1 of the bank 32 refers to an end portion of the opening 34a of the bank 32 on the side opposite to the first electrode 31 side (upper side that is the sealing layer 4 side).

Further, the length (L′) of the portion of the opening sidewall 32a1 of the bank 32 not covered with the edge cover 34 is, of the length connecting the upper end and the lower end of the opening sidewall 32a1 of the bank 32 at the shortest distance along the surface of the opening sidewall 32a1, the length that connects the end portion of the opening 34a of the edge cover 34 positioned on the opening sidewall 32a1 of the bank 32 and the lower end of the opening sidewall 32a1 of the bank 32 at the shortest distance along the surface of the opening sidewall 32a1. Note that the length (L′) of the portion of the opening sidewall 32a1 of the bank 32 not covered with the edge cover 34 can be rephrased as the length of the portion on the opening sidewall 32a1 where the second electrode 33 functions as an electrode (inclined face electrode).

According to the present embodiment, by forming the edge cover 34 in this way, it is possible to suppress leakage (that is, anode-cathode leakage) between the second electrode 33 and the third electrode 36 due to thinning of the EL layer 35 formed on the inclined face of the opening sidewall 32a1. Further, it is possible to cause the light-emitting portion (inclined face light-emitting portion) of the opening sidewall 32a1 to effectively function.

FIG. 17 illustrates, as an example, a case in which the second electrode 33 is patterned while forming the second electrodes 33 only in the opening 32a of the bank 32 including the opening sidewall 32a1 having the inclined face, as described above.

However, the present embodiment is not limited to this example. As long as the edge cover 34 is formed as described above, the second electrode 33 and an auxiliary wiring line 38 may be formed in an island shape for each subpixel SP as described in the first embodiment. In this case as well, similar advantageous effects to those described above can be obtained.

### Sixth Embodiment

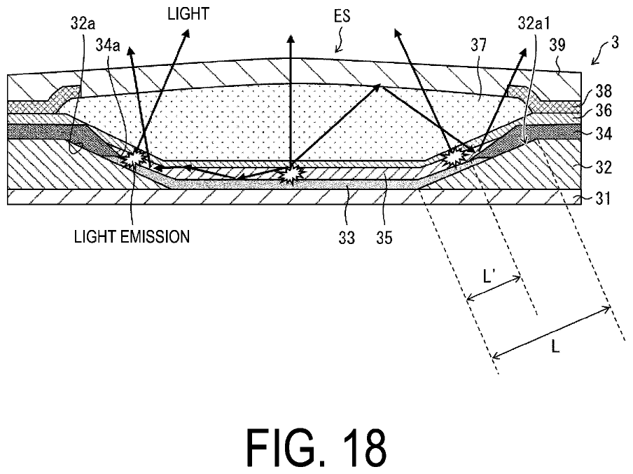

A description of still another embodiment of the disclosure will be described below mainly based on FIG. 18. Note that, for convenience of description, members having the same functions as those of the members described in the above-described embodiments will be denoted by the same reference numerals and signs, and descriptions thereof will not be repeated.

FIG. 18 is a cross-sectional view illustrating a schematic configuration of a light-emitting element layer 3 of a display device 1 according to the present embodiment, together with an optical path of light in a light-emitting region ES in the light-emitting element layer 3.

In the present embodiment, as illustrated in FIG. 18, a second electrode 33 is patterned while positioning an edge of the second electrode 33 in the middle of an opening sidewall 32a1 (that is, in the middle of an inclined face of the opening sidewall 32a1), and an end portion (opening end) of an opening 34a of an edge cover 34 is formed on the opening sidewall 32a1 to cover the edge of the second electrode 33. Note that the middle of the opening sidewall 32a1 refers to a portion between the upper end and the lower end of the opening sidewall 32a1.

Further, in the present embodiment, as described above, the second electrode 33 covers a portion of the opening sidewall 32a1, and the edge cover 34 covers the edge of the second electrode 33 and the portion of the opening sidewall 32a1 not covered with the second electrode 33. As a result, the second electrode 33 is provided with an inclined face along the inclined face of the opening sidewall 32a1 in a portion on the opening sidewall 32a1. Therefore, the EL layer 35 is provided with an inclined face along the inclined face of the second electrode 33 in a portion on the opening sidewall 32a1. Therefore, a third electrode 36 is provided with an inclined face along the inclined face of the second electrode 33 in a portion on the opening sidewall 32a1.

The display device 1 according to the present embodiment is the same as the display devices 1 according to the first to fifth embodiments except for these points.

In the present embodiment as well, when L is defined as the length of the opening sidewall 32a1 of the bank 32 and L′ is defined as the length of the portion of the opening sidewall 32a1 not covered with the edge cover 34, the second electrode 33 and the edge cover 34 are patterned by, for example, photolithography, positioning the end portion of the opening 34a of the edge cover 34 at a position where the L′is longer than ⅓L and shorter than ⅔L. That is, in the present embodiment, the edge cover 34 is formed satisfying ⅓L<L′<⅔L, and the second electrode 33 is patterned in an opening 32a of the bank 32, covering the edge of the second electrode 33 with the edge cover 34. Note that, in the present embodiment as well, similar to the fourth embodiment, the length (L′) of the portion of the opening sidewall 32a1 of the bank 32 not covered with the edge cover 34 can be rephrased as the length of the portion on the opening sidewall 32a1 where the second electrode 33 functions as an electrode (inclined face electrode).

According to the present embodiment as well, by forming the edge cover 34 as described above, it is possible to suppress leakage (that is, anode-cathode leakage) between the second electrode 33 and the third electrode 36 due to thinning of an EL layer 35 formed on the inclined face of the opening sidewall 32a1. Further, it is possible to cause the light-emitting portion (inclined face light-emitting portion) of the opening sidewall 32a1 to effectively function.

Further, according to the present embodiment, in an upper layer overlying the bank 32, the reflective layer in portions other than the opening 32a of the bank 32 is made as small as possible, thereby making it possible to suppress unnecessary reflection.

### First Modified Example

In the first to sixth embodiments described above, description is made using, as an example, a case in which the light-emitting device according to the disclosure is a display device. However, the light-emitting device according to the disclosure is not limited thereto and may be, for example, an illumination device or may be a light-emitting element.

### Second Modified Example

Further, in FIG. 2, FIG. 4, FIG. 13, and FIG. 14, description is made using, as an example, a case in which the bank 32 includes the plurality of openings 32a in each subpixel SP. However, the configuration of the light-emitting device (display device 1, for example) according to the disclosure is not limited to the configuration described above. It is sufficient for the bank 32 to include at least one through hole (first through hole; for example, the opening 32a) in each subpixel SP. Therefore, depending on the relationship between the size of the subpixel SP and the size of the through hole (the opening 32a, for example), only one through hole mentioned above (the opening 32a, for example) needs to be formed in each subpixel SP.

In the first to sixth embodiments described above, description is made using, as an example, a case in which the opening 32a has the small hole shape described above. However, although the opening 32a desirably has the small hole shape described above, the shape thereof is not limited thereto. The shape of the opening 32a is not particularly limited. For example, the opening 32a may be formed in a polygonal shape such as a rectangular shape in a plan view. Similarly, the auxiliary wiring line 38 may also be formed in a polygonal shape such as a rectangular shape in a plan view. In any case, it is desirable for the opening 32a to include the inclined opening sidewall 32a1.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A light-emitting device, comprising:
a bank provided with a first through hole;
a lower layer electrode formed on the bank to close the first through hole;
an upper layer electrode formed above the lower layer electrode;
an EL layer including at least a light-emitting layer and formed between the lower layer electrode and the upper layer electrode to be at least partially adjacent to the lower layer electrode and the upper layer electrode;
a first refractive index layer provided on the upper layer electrode in the first through hole and having a refractive index greater than 1.7;
an auxiliary wiring line provided on the upper layer electrode to be adjacent to the upper layer electrode; and
a second refractive index layer having a lower refractive index than the first refractive index layer and provided on the upper layer electrode to cover the first refractive index layer and the auxiliary wiring line,
wherein the auxiliary wiring line includes a second through hole that is provided corresponding to the first through hole, and
a peripheral edge portion of the auxiliary wiring line surrounding the second through hole covers a peripheral edge portion of the first refractive index layer in a plan view.

2. The light-emitting device according to claim 1,
wherein the first through hole includes an opening sidewall that is inclined,
the lower layer electrode includes an inclined face along at least part of the opening sidewall,
the EL layer includes an inclined face along at least part of the inclined face of the lower layer electrode, and
the upper layer electrode includes an inclined face along at least part of the inclined face of the EL layer.

3. The light-emitting device according to claim 2,
wherein an angle formed by a lower face of the bank and the opening sidewall is in a range from 20° to 30°.

4. The light-emitting device according to claim 2,
wherein an opening diameter at a lower end side of the first through hole is in a range from 10 μm to 20 μm, and an opening diameter at an upper end side of the first through hole is in a range from 12 μm to 65 μm.

5. The light-emitting device according to claim 1,
wherein a height between the upper end and the lower end of the first through hole is in a range from 1 μm to 4 μm.

6. The light-emitting device according to claim 1,
wherein an overlapping width between a peripheral edge portion of the auxiliary wiring line surrounding the second through hole and a peripheral edge portion of the first refractive index layer in a plan view falls within a range from 0.5 μm to a value less than 5.6 μm.

7. The light-emitting device according to claim 6,
wherein the overlapping width between the peripheral edge portion of the auxiliary wiring line surrounding the second through hole and the peripheral edge portion of the first refractive index layer in a plan view is equal to or greater than 1.0 μm.

8. The light-emitting device according to claim 6,
wherein the overlapping width between the peripheral edge portion of the auxiliary wiring line surrounding the second through hole and the peripheral edge portion of the first refractive index layer in a plan view is equal to or less than 2.1 μm.

9. The light-emitting device according to claim 1,
wherein the EL layer includes a hole injection layer containing NiO nanoparticles.

10. The light-emitting device according to claim 1,
wherein the light-emitting layer is a quantum dot light-emitting layer containing a quantum dot.

11. The light-emitting device according to claim 1,
wherein the light-emitting device is a display device including a plurality of subpixels, and
the bank includes at least one first through hole mentioned above in each subpixel.

12. The light-emitting device according to claim 11,
wherein the bank includes, in each of the plurality of subpixels, a plurality of the first through holes each formed in a small hole shape as the first through hole.

13. The light-emitting device according to claim 11, further comprising:
an array substrate including a plurality of thin film transistors; and
a plurality of connection electrodes on the array substrate each formed for a corresponding one among the plurality of subpixels and connected to a corresponding one among the plurality of thin film transistors,
wherein the bank is formed on the array substrate to cover the plurality of connection electrodes in such a manner that the plurality of first through holes expose part of the plurality of connection electrodes, and
the lower layer electrode is connected to the plurality of connection electrodes in the plurality of first through holes.

14. The light-emitting device according to claim 11,
wherein the plurality of subpixels include a red subpixel, a green subpixel, and a blue subpixel,
the lower layer electrode at least includes a reflective electrode and a light-transmissive electrode formed on the reflective electrode, and
in at least two subpixels of the red subpixel, the green subpixel, and the blue subpixel, layer thicknesses of the light-transmissive electrodes differ from each other.

15. The light-emitting device according to claim 11,
wherein the lower layer electrode is formed in an island shape for each of the plurality of subpixels.

16. The light-emitting device according to claim 15, further comprising:
an edge cover, on the bank, including a third through hole corresponding to the first through hole in such a manner as to open the first through hole,
wherein the edge cover covers a portion of the lower layer electrode located on an upper face of the bank.

17. The light-emitting device according to claim 11,
wherein the lower layer electrode is formed in an island shape for each of the plurality of first through holes.

18. (canceled)

19. The light-emitting device according to claim 1,
wherein the lower layer electrode is formed only in the first through hole.

20. The light-emitting device according to claim 2,
wherein the lower layer electrode is formed with an edge of the lower layer electrode located between the upper end and the lower end of the opening sidewall.

21. The light-emitting device according to claim 20, further comprising:
an edge cover, on the bank, including a third through hole having an opening end on the opening sidewall of the bank,
wherein a relation of ⅓L<L′<⅔L is satisfied, where L is a length of the opening sidewall of the bank and L′is a length of a portion of the opening sidewall not covered with the edge cover.

22. (canceled)
